(19) United States
(12) Patent Application Publication
(10) Pub. No.: US 2026/0060017 A1
(43) Pub. Date: Feb. 26, 2026

(54) SUBSTRATE PROCESSING METHOD, SUBSTRATE PROCESSING APPARATUS, AND SUBSTRATE PROCESSING LIQUID

(71) Applicant: SCREEN Holdings Co., Ltd., Kyoto (JP)

(72) Inventors: Yosuke HANAWA, Kyoto (JP); Akiko HARUMOTO, Kyoto (JP); Dai UEDA, Kyoto (JP)

(21) Appl. No.: 19/099,465

(22) PCT Filed: May 24, 2023
(86) PCT No.: PCT/JP2023/019337

§ 371 Date: Jan. 28, 2025

(30) Foreign Application Priority Data
Jul. 28, 2022 (JP) 2022-120451

(51) Int. Cl. H01L 21/311; H01L 21/67

(52) U.S. Cl. CPC H01L 21/31111; H01L 21/6708

(57) ABSTRACT

The present invention relates to a substrate processing method, a substrate processing apparatus, and a substrate processing liquid. In the substrate processing method, a substrate W including a first layer G is processed. A second mixed liquid P2 contains an etching liquid and iodide ions (I⁻). The substrate processing method includes a first adjustment step and an etching step. In the first adjustment step, at least one of oxygen and ozone is added to the second mixed liquid P2. In the etching step, the second mixed liquid P2 adjusted in the first adjustment step is supplied to the substrate W. In the etching step, the first layer G is etched.

### TECHNICAL FIELD

The present invention relates to a substrate processing method, a substrate processing apparatus, and a substrate processing liquid for processing a substrate. The substrate is, for example, a semiconductor wafer, a liquid crystal display substrate, an organic electroluminescence (EL) substrate, a flat panel display (FPD) substrate, an optical display substrate, a magnetic disk substrate, an optical disk substrate, a magneto-optical disk substrate, a photomask substrate, or a solar cell substrate.

### BACKGROUND ART

Patent Literature 1 discloses a substrate processing method for processing a substrate. The substrate includes a first layer. In the substrate processing method of Patent Literature 1, a substrate processing liquid is supplied to the substrate. The substrate processing liquid contains an etching liquid. The substrate processing liquid further contains an iodide. The iodide is, for example, tetraethylammonium iodide (TEAI). The first layer is exposed to the substrate processing liquid. The first layer is etched with the substrate processing liquid. At least a part of the first layer is removed by etching the first layer.

The first layer is, for example, an interlayer film. The substrate further includes a second layer and a third layer. The interlayer film is disposed between the second layer and the third layer. When the first layer is an interlayer film, the first layer is selectively etched. Specifically, the first layer is etched while the etching of the second layer and the third layer is suppressed. A recess is formed by selectively etching the first layer. The recess is a space. The recess is located between the second layer and the third layer. The second layer, the recess, and the third layer constitute a pattern having an uneven shape.

### CITATION LIST

### Patent Literature

Patent Literature 1: JP 2021-48369 A

### SUMMARY OF INVENTION

### Technical Problem

In recent years, the first layer has become smaller. For example, the interlayer film has become thin. For example, the recess has become narrow. For example, the pattern has become fine.

As the first layer become smaller, it may be more difficult to properly etch the first layer. For example, as the first layer becomes smaller, the etching rate of the first layer may decrease.

The present invention has been made in view of such circumstances, and an object of the present invention is to provide a substrate processing method, a substrate processing apparatus, and a substrate processing liquid capable of appropriately etching a first layer even when the first layer is small.

### Solution to Problem

The present inventors have intensively studied to solve the above problems. As described above, the substrate processing liquid contains iodide. The iodide releases iodide ions (I⁻) into the substrate processing liquid. The iodide ion (I⁻) is a monovalent monoatomic anion composed of one iodine atom.

The present inventors have paid attention to the iodide ions (I⁻) in the substrate processing liquid. The present inventors have assumed that the iodide ions (I⁻) in the substrate processing liquid assist the etching of the first layer.

In the substrate processing liquid, the iodide ions (I⁻) may change to molecular iodine (I₂). In the substrate processing liquid, the iodide ions (I⁻) may change to triiodide ions (I₃⁻). The triiodide ion (I₃⁻) is a monovalent polyatomic anion composed of three iodine atoms. When the iodide ions (I⁻) change to at least one of molecular iodine (I₂) and triiodide ions (I₃⁻), the amount of the iodide ions (I⁻) in the substrate processing liquid decreases.

The present inventors have assumed that the molecular iodine (I₂) does not assist the etching of the first layer. The present inventors have assumed that the triiodide ions (I₃⁻) do not assist the etching of the first layer. Therefore, the present inventors have assumed that it is preferable to prevent the change from the iodide ions (I⁻) to the molecular iodine (I₂). The present inventors have assumed that it is preferable to prevent the change from the iodide ions (I⁻) to the triiodide ions (I₃⁻).

However, various experiments have negated our assumption. The present inventors have found that the molecular iodine (I₂) assists the etching of the first layer. The present inventors have found that the triiodide ions (I₃⁻) assist etching of the first layer.

The present invention has been obtained by further conducting intensive studies on the basis of these findings, and has the following configuration. That is, the present invention is a substrate processing method for processing a substrate including a first layer, the method including: a first preparation step of adding at least one of molecular iodine (I₂) and triiodide to an etching liquid to prepare a first mixed liquid; and an etching step of supplying the first mixed liquid to the substrate to etch the first layer.

The substrate processing method is for processing the substrate. The substrate includes the first layer.

The substrate processing method includes a first preparation step. In the first preparation step, a first mixed liquid is prepared. The first mixed liquid is obtained by adding at least one of molecular iodine (I₂) and triiodide to an etching liquid. When the first mixed liquid is prepared by adding the molecular iodine (I₂) to the etching liquid, the amount of the molecular iodine (I₂) in the first mixed liquid is large. When the first mixed liquid is prepared by adding the triiodide to the etching liquid, the amount of the triiodide ions (I₃⁻) in the first mixed liquid is large. Therefore, at least one of the content of the molecular iodine (I₂) in the first mixed liquid and the content of the triiodide ions (I₃⁻) in the first mixed liquid is high.

Here, the “triiodide” is a salt containing triiodide ions (I₃⁻). Triiodide is also referred to as “triiodide salt”. Triiodide releases the triiodide ions (I₃⁻).

The substrate processing method includes an etching step. In the etching step, the first mixed liquid is supplied to the substrate. In the etching step, the first layer is exposed to the first mixed liquid. The etching liquid etches the first layer. At least one of the molecular iodine (I₂) and the triiodide ions (I₃⁻) assists the etching of the first layer. As described above, the first mixed liquid abundantly contains at least one of the molecular iodine (I₂) and the triiodide ions (I₃⁻). Therefore, even when the first layer is small, the first layer is appropriately etched in the etching step.

As described above, according to the substrate processing method of the present invention, the first layer can be appropriately etched even when the first layer is small.

The present invention is a substrate processing method for processing a substrate including a first layer, the substrate processing method including: a second preparation step of adding at least one of molecular iodine (I₂) and triiodide to a solvent to prepare a first solution; and an etching step of supplying the first solution and an etching liquid to the substrate to etch the first layer.

The substrate processing method is for processing the substrate. The substrate includes the first layer.

The substrate processing method includes a second preparation step. In the second preparation step, a first solution is prepared. The first solution is obtained by adding at least one of molecular iodine (I₂) and triiodide to a solvent. When the first solution is prepared by adding the molecular iodine (I₂) to the solvent, the amount of the molecular iodine (I₂) in the first solution is large. When the first solution is prepared by adding the triiodide to the solvent, the amount of the triiodide ions (I₃⁻) in the first solution is large. Therefore, at least one of the content of the molecular iodine (I₂) in the first solution and the content of the triiodide ions (I₃⁻) in the first solution is high.

The substrate processing method includes an etching step. In the etching step, the first solution is supplied to the substrate. In the etching step, the etching liquid is supplied to the substrate. In the etching step, the first layer is exposed to the first solution and the etching liquid. The etching liquid etches the first layer. At least one of the molecular iodine (I₂) and the triiodide ions (I₃⁻) assists the etching of the first layer. As described above, the first solution abundantly contains at least one of the molecular iodine (I₂) and the triiodide ions (I₃⁻). Therefore, even when the first layer is small, the first layer is appropriately etched in the etching step.

As described above, according to the substrate processing method of the present invention, the first layer can be appropriately etched even when the first layer is small.

In the substrate processing method described above, the triiodide preferably includes at least one of nitrogen triiodide, phosphorus triiodide, and ammonium triiodide. Nitrogen triiodide readily releases the triiodide ions (I₃⁻). Therefore, when the triiodide includes nitrogen triiodide, it is easy to prepare the first mixed liquid rich in triiodide ions (I₃⁻) or the first solution rich in triiodide ions (I₃⁻). Similarly, phosphorus triiodide readily releases the triiodide ions (I₃⁻). Therefore, when the triiodide includes phosphorus triiodide, it is easy to prepare the first mixed liquid rich in triiodide ions (I₃⁻) or the first solution rich in triiodide ions (I₃⁻). Ammonium triiodide readily releases the triiodide ions (I₃⁻). Thus, when the triiodide includes ammonium triiodide, it is easy to prepare the first mixed liquid rich in triiodide ions (I₃⁻) or the first solution rich in triiodide ions (I₃⁻).

The present invention is a substrate processing method for processing a substrate including a first layer, the substrate processing method including: a first adjustment step of adding at least one of oxygen and ozone to a second mixed liquid containing an etching liquid and iodide ions (I⁻); and an etching step of supplying the second mixed liquid adjusted in the first adjustment step to the substrate to etch the first layer.

The substrate processing method is for processing the substrate. The substrate includes the first layer.

A second mixed liquid contains an etching liquid and iodide ions (I⁻). The substrate processing method includes a first adjustment step. In the first adjustment step, at least one of oxygen and ozone is added to the second mixed liquid. In the first adjustment step, the iodide ions (I⁻) in the second mixed liquid are oxidized. Specifically, in the first adjustment step, the iodide ions (I⁻) in the second mixed liquid change to at least one of the molecular iodine (I₂) and the triiodide ions (I₃⁻). Therefore, at least one of the amount of the molecular iodine (I₂) in the second mixed liquid and the amount of the triiodide ions (I₃⁻) in the second mixed liquid increases. That is, at least one of the content of the molecular iodine (I₂) in the second mixed liquid and the content of the triiodide ions (I₃⁻) in the second mixed liquid becomes high.

The substrate processing method includes an etching step. In the etching step, the second mixed liquid adjusted in the first adjustment step is supplied to the substrate. In the etching step, the first layer is exposed to the second mixed liquid adjusted in the first adjustment step. The etching liquid etches the first layer. At least one of the molecular iodine (I₂) and the triiodide ions (I₃⁻) assists the etching of the first layer. As described above, the second mixed liquid adjusted in the first adjustment step abundantly contains at least one of the molecular iodine (I₂) and the triiodide ions (I₃⁻). Therefore, even when the first layer is small, the first layer is appropriately etched in the etching step.

As described above, according to the substrate processing method of the present invention, the first layer can be appropriately etched even when the first layer is small.

The present invention is a substrate processing method for processing a substrate including a first layer, the substrate processing method including: a second adjustment step of adding at least one of oxygen and ozone to a second solution containing iodide ions (I⁻); and an etching step of supplying the second solution adjusted in the second adjustment step and an etching liquid to the substrate to etch the first layer.

The substrate processing method is for processing the substrate. The substrate includes the first layer.

The second solution contains the iodide ions (I⁻). The substrate processing method includes a second adjustment step. In the second adjustment step, at least one of oxygen and ozone is added to the second solution. In the second adjustment step, the iodide ions (I⁻) in the second solution are oxidized. Specifically, in the second adjustment step, the iodide ions (I⁻) in the second solution change to at least one of the molecular iodine (I₂) and the triiodide ions (I₃⁻). Therefore, at least one of the amount of the molecular iodine (I₂) in the second solution and the amount of the triiodide ions (I₃⁻) in the second solution increases. That is, at least one of the content of the molecular iodine (I₂) in the second solution and the content of the triiodide ions (I₃⁻) in the second solution becomes high.

The substrate processing method includes an etching step. In the etching step, the second solution adjusted in the second adjustment step is supplied to the substrate. In the etching step, an etching liquid is supplied to the substrate. In the etching step, the first layer is exposed to the second solution adjusted in the second adjustment step. In the etching step, the first layer is exposed to the etching liquid. The etching liquid etches the first layer. At least one of the molecular iodine (I₂) and the triiodide ions (I₃⁻) assists the etching of the first layer. As described above, the second solution prepared in the second adjustment step abundantly contains at least one of the molecular iodine (I₂) and the triiodide ions (I₃⁻). Therefore, even when the first layer is small, the first layer is appropriately etched in the etching step.

As described above, according to the substrate processing method of the present invention, the first layer can be appropriately etched even when the first layer is small.

In the substrate processing method described above, the oxygen preferably includes at least one of oxygen gas and high concentration oxygen water. By adding at least one of oxygen gas and high concentration oxygen water to the second mixed liquid, the iodide ions (I⁻) in the second mixed liquid are easily oxidized. Therefore, it is easy to increase at least one of the amount of the molecular iodine (I₂) in the second mixed liquid and the amount of the triiodide ions (I₃⁻) in the second mixed liquid in the first adjustment step. Similarly, by adding at least one of oxygen gas and high concentration oxygen water to the second solution, the iodide ions (I⁻) in the second solution are easily oxidized. Therefore, it is easy to increase at least one of the amount of the molecular iodine (I₂) in the second solution and the amount of the triiodide ions (I₃⁻) in the second solution in the second adjustment step.

Here, the high concentration oxygen water is water containing oxygen at a concentration higher than usual. The amount of oxygen in high concentration oxygen water is greater than the amount of oxygen in water placed in normal air.

In the substrate processing method described above, the ozone preferably includes at least one of ozone gas and ozone water. By adding at least one of ozone gas and ozone water to the second mixed liquid, the iodide ions (I⁻) in the second mixed liquid are easily oxidized. Therefore, it is easy to increase at least one of the amount of the molecular iodine (I₂) in the second mixed liquid and the amount of the triiodide ions (I₃⁻) in the second mixed liquid in the first adjustment step. Similarly, by adding at least one of ozone gas and ozone water to the second solution, iodide ions (I⁻) in the second solution are easily oxidized. Therefore, when ozone includes at least one of ozone gas and ozone water, it is easy to increase at least one of the amount of the molecular iodine (I₂) in the second solution and the amount of the triiodide ions (I₃⁻) in the second solution in the second adjustment step.

Here, the ozone water is water containing dissolved ozone.

In the substrate processing method described above, it is preferable that the first layer contains silicon oxide, and the etching liquid contains hydrogen fluoride. The first layer contains silicon oxide. The etching liquid contains hydrogen fluoride. It is easy to etch silicon oxide with hydrogen fluoride. Therefore, it is easy to etch the first layer in the etching step. At least one of the molecular iodine (I₂) and the triiodide ions (I₃⁻) assists etching of silicon oxide. Therefore, even when the first layer is small, the first layer is appropriately etched in the etching step.

In the substrate processing method described above, it is preferable that the substrate further includes a second layer having a composition different from a composition of the first layer, the second layer is in contact with the first layer, and in the etching step, the first layer is etched while suppressing etching of the second layer. The substrate includes a second layer. The second layer has a composition different from the composition of the first layer. Therefore, etching of the second layer is suitably suppressed in the etching step. The second layer is in contact with the first layer. Even when the first layer is in contact with the second layer, at least one of the molecular iodine (I₂) and the triiodide ions (I₃⁻) suitably assists the etching of the first layer. Therefore, even when the first layer in contact with the second layer is small, the first layer is appropriately etched in the etching step.

In the substrate processing method described above, it is preferable that the first layer contains silicon oxide, the second layer contains at least one of single crystal silicon, polycrystalline silicon, amorphous silicon, and silicon nitride, and the etching liquid contains hydrogen fluoride. The first layer contains silicon oxide. The second layer contains at least one of single crystal silicon, polycrystalline silicon, amorphous silicon, and silicon nitride. The etching liquid contains hydrogen fluoride. It is easy to etch silicon oxide with hydrogen fluoride. It is difficult to etch at least one of single crystal silicon, polycrystalline silicon, amorphous silicon, and silicon nitride with hydrogen fluoride. Therefore, in the etching step, it is easy to etch the first layer while suppressing the etching of the second layer. Even when the first layer is in contact with the second layer, at least one of the molecular iodine (I₂) and the triiodide ions (I₃⁻) assists the etching of the silicon oxide of the first layer. Therefore, even when the first layer in contact with the second layer is small, the first layer is appropriately etched in the etching step.

In the substrate processing method described above, it is preferable that the substrate further includes: a second layer having a composition different from a composition of the first layer; and a third layer having a composition different from a composition of the first layer, the first layer is disposed between the second layer and the third layer, the second layer is in contact with the first layer, the third layer is in contact with the first layer, and in the etching step, the first layer is etched while suppressing etching of the second layer and the third layer. The substrate includes the second layer and the third layer. The second layer has a composition different from the composition of the first layer. Therefore, etching of the second layer is suitably suppressed in the etching step. The third layer has a composition different from the composition of the first layer. Therefore, etching of the third layer is suitably suppressed in the etching step. The second layer is in contact with the first layer. The third layer is in contact with the first layer. Even when the first layer is in contact with the second layer and the third layer, at least one of the molecular iodine (I₂) and the triiodide ions (I₃⁻) assists etching of the first layer. Therefore, even when the first layer in contact with the second layer and the third layer is small, the first layer is appropriately etched in the etching step.

In the substrate processing method described above, it is preferable that the first layer contains silicon oxide, the second layer contains at least one of single crystal silicon, polycrystalline silicon, amorphous silicon, and silicon nitride, the third layer contains at least one of single crystal silicon, polycrystalline silicon, amorphous silicon, and silicon nitride, and the etching liquid contains hydrogen fluoride. The first layer contains silicon oxide. The second layer contains at least one of single crystal silicon, polycrystalline silicon, amorphous silicon, and silicon nitride. The third layer contains at least one of single crystal silicon, polycrystalline silicon, amorphous silicon, and silicon nitride. The etching liquid contains hydrogen fluoride. It is easy to etch silicon oxide with hydrogen fluoride. It is difficult to etch at least one of single crystal silicon, polycrystalline silicon, amorphous silicon, and silicon nitride with hydrogen fluoride. Therefore, in the etching step, it is easy to etch the first layer while suppressing the etching of the second layer and the third layer. Even when the first layer is in contact with the second layer and the third layer, at least one of the molecular iodine (I₂) and the triiodide ions (I₃⁻) assists the etching of the silicon oxide of the first layer. Therefore, even when the first layer in contact with the second layer and the third layer is small, the first layer is appropriately etched in the etching step.

The present invention is a substrate processing apparatus that processes a substrate including a first layer, the substrate processing apparatus including: a first generation unit that generates a first mixed liquid by adding at least one of molecular iodine (I₂) and triiodide to an etching liquid; and a first supply unit that supplies the first mixed liquid to the substrate to etch the first layer.

The substrate processing apparatus processes the substrate. The substrate includes the first layer.

The substrate processing apparatus includes the first generation unit. The first generation unit generates the first mixed liquid. The first mixed liquid is obtained by adding at least one of molecular iodine (I₂) and triiodide to an etching liquid. When the first mixed liquid is generated by adding the molecular iodine (I₂) to the etching liquid, the amount of the molecular iodine (I₂) in the first mixed liquid is large. When the first mixed liquid is generated by adding the triiodide to the etching liquid, the amount of the triiodide ions (I₃⁻) in the first mixed liquid is large. Therefore, at least one of the content of the molecular iodine (I₂) in the first mixed liquid and the content of the triiodide ions (I₃) in the first mixed liquid is high.

The substrate processing apparatus includes the first supply unit. The first supply unit supplies the first mixed liquid to the substrate. The first layer is exposed to the first mixed liquid. The etching liquid etches the first layer. At least one of the molecular iodine (I₂) and the triiodide ions (I₃) assists the etching of the first layer. As described above, the first mixed liquid abundantly contains at least one of the molecular iodine (I₂) and the triiodide ions (I₃⁻). Therefore, even when the first layer is small, the first layer is appropriately etched.

As described above, according to the substrate processing apparatus of the present invention, the first layer can be appropriately etched even when the first layer is small.

The present invention is a substrate processing apparatus that processes a substrate including a first layer, the substrate processing apparatus including: a second generation unit that generates a first solution by adding at least one of molecular iodine (I₂) and triiodide to a solvent; and a second supply unit that supplies the first solution and an etching liquid to the substrate to etch the first layer.

The substrate processing apparatus processes the substrate. The substrate includes the first layer.

The substrate processing apparatus includes the second generation unit. The second generation unit generates the first solution. The first solution is obtained by adding at least one of molecular iodine (I₂) and triiodide to a solvent. When the first solution is generated by adding the molecular iodine (I₂) to the solvent, the amount of the molecular iodine (I₂) in the first solution is large. When the first solution is generated by adding the triiodide to the solvent, the amount of the triiodide ions (I₃⁻) in the first solution is large. Therefore, at least one of the content of the molecular iodine (I₂) in the first solution and the content of the triiodide ions (I₃⁻) in the first solution is high.

The substrate processing apparatus includes the second supply unit. The second supply unit supplies the first solution to the substrate. The second supply unit supplies the etching liquid to the substrate. The first layer is exposed to the first solution and the etching liquid. The etching liquid etches the first layer. At least one of the molecular iodine (I₂) and the triiodide ions (I₃⁻) assists the etching of the first layer. As described above, the first solution abundantly contains at least one of the molecular iodine (I₂) and the triiodide ions (I₃⁻). Therefore, even when the first layer is small, the first layer is appropriately etched.

As described above, according to the substrate processing apparatus of the present invention, the first layer can be appropriately etched even when the first layer is small.

The present invention is a substrate processing apparatus that processes a substrate including a first layer, the substrate processing apparatus including: a first adjustment unit that adds at least one of oxygen and ozone to a second mixed liquid containing an etching liquid and iodide ions (I⁻); and a third supply unit that supplies the second mixed liquid adjusted by the first adjustment unit to the substrate to etch the first layer.

The substrate processing apparatus processes the substrate. The substrate includes the first layer.

A second mixed liquid contains an etching liquid and iodide ions (I⁻). The substrate processing apparatus includes the first adjustment unit. The first adjustment unit adds at least one of oxygen and ozone to the second mixed liquid. The iodide ions (I⁻) in the second mixed liquid are oxidized. Specifically, the iodide ions (I⁻) in the second mixed liquid change to at least one of the molecular iodine (I₂) and the triiodide ions (I₃⁻). Therefore, at least one of the amount of the molecular iodine (I₂) in the second mixed liquid and the amount of the triiodide ions (I₃⁻) in the second mixed liquid increases. That is, at least one of the content of the molecular iodine (I₂) in the second mixed liquid and the content of the triiodide ions (I₃⁻) in the second mixed liquid becomes high.

The substrate processing apparatus includes the third supply unit. The third supply unit supplies the second mixed liquid adjusted by the first adjustment unit to the substrate. The first layer is exposed to the second mixed liquid adjusted by the first adjustment unit. The etching liquid etches the first layer. At least one of the molecular iodine (I₂) and the triiodide ions (I₃⁻) assists the etching of the first layer. As described above, the second mixed liquid adjusted by the first adjustment unit abundantly contains at least one of the molecular iodine (I₂) and the triiodide ions (I₃⁻). Therefore, even when the first layer is small, the first layer is appropriately etched.

As described above, according to the substrate processing apparatus of the present invention, the first layer can be appropriately etched even when the first layer is small.

The present invention is a substrate processing apparatus that processes a substrate including a first layer, the substrate processing apparatus including: a second adjustment unit that adds at least one of oxygen and ozone to a second solution containing iodide ions (I⁻); and a fourth supply unit that supplies the second solution adjusted by the second adjustment unit and an etching liquid to the substrate to etch the first layer.

The substrate processing apparatus processes the substrate. The substrate includes the first layer.

The second solution contains the iodide ions (I⁻). The substrate processing apparatus includes the second adjustment unit. The second adjustment unit adds at least one of oxygen and ozone to the second solution. The iodide ions (I⁻) in the second solution are oxidized. Specifically, the iodide ions (I⁻) in the second solution change to at least one of the molecular iodine (I₂) and the triiodide ions (I₃⁻). Therefore, at least one of the amount of the molecular iodine (I₂) in the second solution and the amount of the triiodide ions (I₃⁻) in the second solution increases. That is, at least one of the content of the molecular iodine (I₂) in the second solution and the content of the triiodide ions (I₃⁻) in the second solution becomes high.

The substrate processing apparatus includes the fourth supply unit. The fourth supply unit supplies the second solution adjusted by the second adjustment unit to the substrate. The fourth supply unit supplies the etching liquid to the substrate. The first layer is exposed to the second solution adjusted in the second adjustment unit. The first layer is exposed to the etching liquid. The etching liquid etches the first layer. At least one of the molecular iodine (I₂) and the triiodide ions (I₃⁻) assists the etching of the first layer. As described above, the second solution adjusted by the second adjustment unit abundantly contains at least one of the molecular iodine (I₂) and the triiodide ions (I₃⁻). Therefore, even when the first layer is small, the first layer is appropriately etched.

As described above, according to the substrate processing apparatus of the present invention, the first layer can be appropriately etched even when the first layer is small.

The present invention is a substrate processing liquid for processing a substrate including a first layer, wherein the first layer contains silicon oxide, the substrate processing liquid contains an etching liquid, the etching liquid contains hydrogen fluoride, and the substrate processing liquid is obtained by adding at least one of molecular iodine (I₂) and triiodide to the etching liquid.

The substrate processing liquid is for processing the substrate. The substrate includes the first layer. The first layer contains silicon oxide. The substrate processing liquid contains an etching liquid. The etching liquid contains hydrogen fluoride. It is easy to etch silicon oxide with hydrogen fluoride. Therefore, the substrate processing liquid easily etches the first layer.

The substrate processing liquid is obtained by adding at least one of molecular iodine (I₂) and triiodide to the etching liquid. When the substrate processing liquid is obtained by adding the molecular iodine (I₂) to the etching liquid, the amount of the molecular iodine (I₂) in the substrate processing liquid is large. When the substrate processing liquid is obtained by adding the triiodide to the etching liquid, the amount of the triiodide ions (I₃⁻) in the substrate processing liquid is large. Therefore, at least one of the content of the molecular iodine (I₂) in the substrate processing liquid and the content of the triiodide ions (I₃⁻) in the substrate processing liquid is high. That is, the substrate processing liquid abundantly contains at least one of the molecular iodine (I₂) and the triiodide ions (I₃⁻). Here, at least one of the molecular iodine (I₂) and the triiodide ions (I₃⁻) assists etching of silicon oxide. Therefore, even when the first layer is small, the substrate processing liquid appropriately etches the first layer.

As described above, according to the substrate processing liquid of the present invention, the first layer can be appropriately etched even when the first layer is small.

### Advantageous Effects of Invention

According to the substrate processing method, the substrate processing apparatus, and the substrate processing liquid of the present invention, the first layer can be appropriately etched even when the first layer is small.

### BRIEF DESCRIPTION OF DRAWINGS

FIG. 1 is a plan view illustrating the inside of a substrate processing apparatus.

FIG. 2 is a control block diagram of the substrate processing apparatus.

FIG. 3(a) is a side view of the substrate. FIG. 3(b) is a plan view of the substrate.

FIGS. 4(a) and 4(b) are diagrams each illustrating an example of a first layer.

FIGS. 5(a) and 5(b) are diagrams each illustrating another example of a second layer.

FIG. 6 is a diagram illustrating a configuration of a processing unit and a first adjustment unit of a first embodiment.

FIG. 7 is a flowchart illustrating a procedure of a substrate processing method of the first embodiment.

FIG. 8 is a table showing Example 1 and Comparative Examples 1 and 2.

FIGS. 9(a) and 9(b) are diagrams schematically illustrating the first layer.

FIG. 10 is a diagram illustrating a configuration of a processing unit and a second adjustment unit of a second embodiment.

FIG. 11 is a flowchart illustrating a procedure of a substrate processing method of a second embodiment.

FIG. 12 is a diagram illustrating a configuration of a processing unit and a first generation unit of a third embodiment.

FIG. 13 is a flowchart showing a procedure of a substrate processing method of the third embodiment.

FIG. 14 is a diagram illustrating a configuration of a processing unit and a second generation unit of a fourth embodiment.

FIG. 15 is a flowchart illustrating a procedure of a substrate processing method of the fourth embodiment.

FIG. 16 is a diagram illustrating a configuration of a processing unit and a first adjustment unit of a modification.

### DESCRIPTION OF EMBODIMENTS

Hereinafter, a substrate processing method, a substrate processing apparatus, and a substrate processing liquid of the present invention will be described with reference to the drawings.

### 1. First Embodiment

### 1-1. Outline of Substrate Processing Apparatus

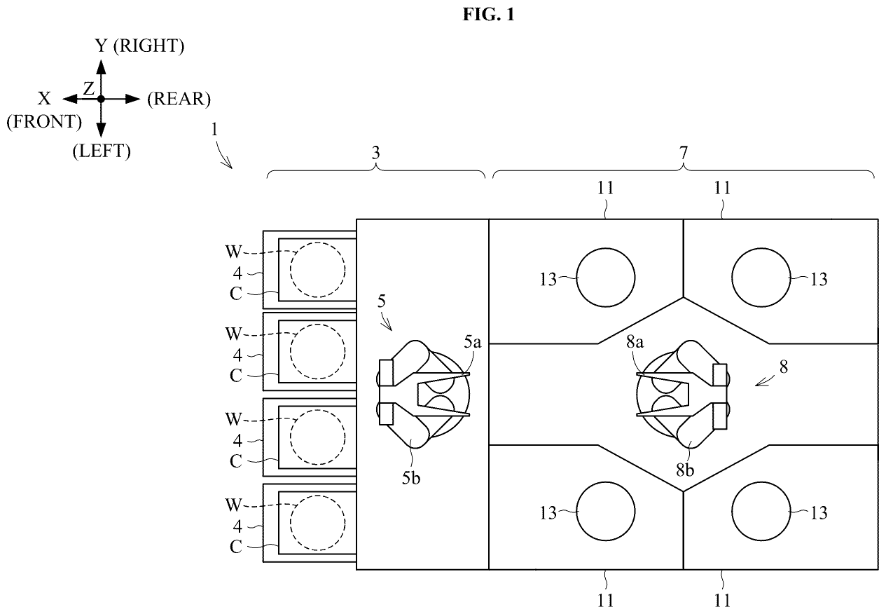

FIG. 1 is a plan view illustrating the inside of a substrate processing apparatus 1. The substrate processing apparatus 1 performs processing on a substrate W. The processing in the substrate processing apparatus 1 includes wet etching processing.

The substrate processing apparatus 1 includes an indexer unit 3 and a processing block 7. The processing block 7 is connected to the indexer unit 3. The indexer unit 3 supplies the substrate W to the processing block 7. The processing block 7 performs processing on the substrate W. The indexer unit 3 collects the substrate W from the processing block 7.

In the present specification, for convenience, the direction in which the indexer unit 3 and the processing block 7 are arranged is referred to as a “front-rear direction X”. The front-rear direction X is horizontal. Of the front-rear direction X, the direction from the processing block 7 toward the indexer unit 3 is referred to as “front”. A direction opposite to the front is referred to as “rear”. A direction orthogonal to the front-rear direction X is referred to as a “width direction Y”. The width direction Y is horizontal. One direction in the “width direction Y” is appropriately referred to as a “right side”. A direction opposite to the right side is referred to as a “left side”. When the front-rear direction X and the width direction Y are not distinguished, they are simply referred to as a “horizontal direction”. A direction perpendicular to the horizontal direction is referred to as a “vertical direction Z”. In each drawing, front, rear, right, left, up, and down are appropriately shown for reference.

The indexer unit 3 includes a plurality of (for example, four) carrier placement portions 4. Each of the carrier placing portions 4 places one carrier C. The carrier C accommodates a plurality of substrates W. The carrier C is, for example, a front opening unified pod (FOUP), a standard mechanical interface (SMIF), or an open cassette (OC).

The indexer unit 3 includes a transport mechanism 5. The transport mechanism 5 is disposed behind the carrier placing portions 4. The transport mechanism 5 transports the substrate W. The transport mechanism 5 is configured to access the carrier C placed on the carrier placing portion 4. The transport mechanism 5 is configured to take out the substrate W from the carrier C placed on the carrier placing portion 4 and put the substrate W into the carrier C placed on the carrier placing portion 4.

The transport mechanism 5 includes a hand 5a and a hand drive portion 5b. The hand 5a supports the substrate W. The hand drive portion 5b is coupled to the hand 5a. The hand drive portion 5b moves the hand 5a. The hand drive portion 5b moves the hand 5a in, for example, the front-rear direction X, the width direction Y, and the vertical direction Z. The hand drive portion 5b rotates the hand 5a in a horizontal plane, for example.

The processing block 7 includes a transport mechanism 8. The transport mechanism 8 transports the substrate W. The transport mechanism 8 is configured to receive the substrate W from the transport mechanism 5 and to pass the substrate W to the transport mechanism 5.

The transport mechanism 8 includes a hand 8a and a hand drive portion 8b. The hand 8a supports the substrate W. The hand drive portion 8b is coupled to the hand 8a. The hand drive portion 8b moves the hand 8a. The hand drive portion 8b moves the hand 8a in, for example, the front-rear direction X, the width direction Y, and the vertical direction Z. The hand drive portion 8b rotates the hand 8a in a horizontal plane, for example.

The processing block 7 includes a plurality of processing units 11. The processing unit 11 is disposed on the side of the transport mechanism 8. Each processing unit 11 performs processing on the substrate W.

Each processing unit 11 includes a substrate holding unit 13. The substrate holding unit 13 holds the substrate W.

The transport mechanism 8 is configured to access each processing unit 11. The transport mechanism 8 is configured to pass the substrate W to the substrate holding unit 13 and to take the substrate W from the substrate holding unit 13.

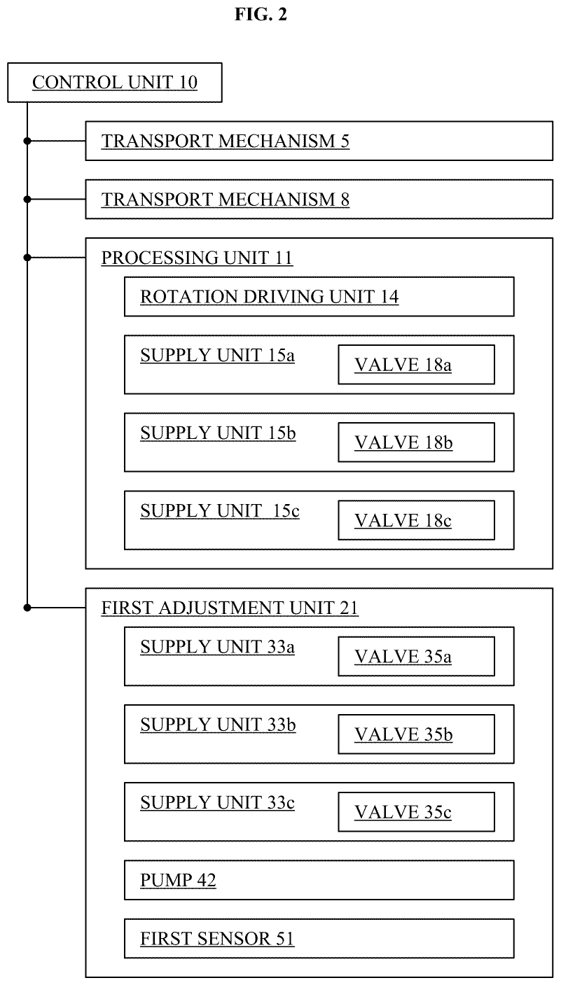

FIG. 2 is a control block diagram of the substrate processing apparatus 1. The substrate processing apparatus 1 includes a control unit 10. The control unit 10 is communicably connected to the transport mechanisms 5 and 8 and the processing unit 11. The control unit 10 controls the transport mechanisms 5 and 8 and the processing unit 11.

The control unit 10 is realized by a central processing unit (CPU) that executes various pieces of processing, a random-access memory (RAM) that is a work area of arithmetic processing, a storage medium such as a fixed disk, and the like. The control unit 10 has various types of information stored in advance in a storage medium. The information included in the control unit 10 includes, for example, transportation condition information and processing condition information. The transportation condition information defines a condition related to the operation of the transport mechanisms 5 and 8. The processing condition information defines a condition related to the operation of the processing unit 11. The processing condition information is also referred to as a processing recipe.

An operation example of the substrate processing apparatus 1 will be briefly described.

The transport mechanism 5 transports the substrate W from the carrier C to the transport mechanism 8.

The transport mechanism 8 distributes the substrate W to the processing units 11. Specifically, the transport mechanism 8 transports the substrate W from the transport mechanism 5 to the substrate holding unit 13 of each processing unit 11.

Each processing unit 11 processes the substrate W held by the substrate holding unit 13. Each processing unit 11 performs, for example, wet etching processing on the substrate W.

After the processing unit 11 processes the substrate W, the transport mechanism 8 collects the substrate W from the processing unit 11. Specifically, the transport mechanism 8 transports the substrate W from the substrate holding unit 13 of each processing unit 11 to the transport mechanism 5.

The transport mechanism 5 transports the substrate W from the transport mechanism 8 to the carrier C.

### 1-2. Structure of Substrate W

The substrate W is, for example, a semiconductor wafer, a liquid crystal display substrate, an organic electroluminescence (EL) substrate, a flat panel display (FPD) substrate, an optical display substrate, a magnetic disk substrate, an optical disk substrate, a magneto-optical disk substrate, a photomask substrate, or a solar cell substrate.

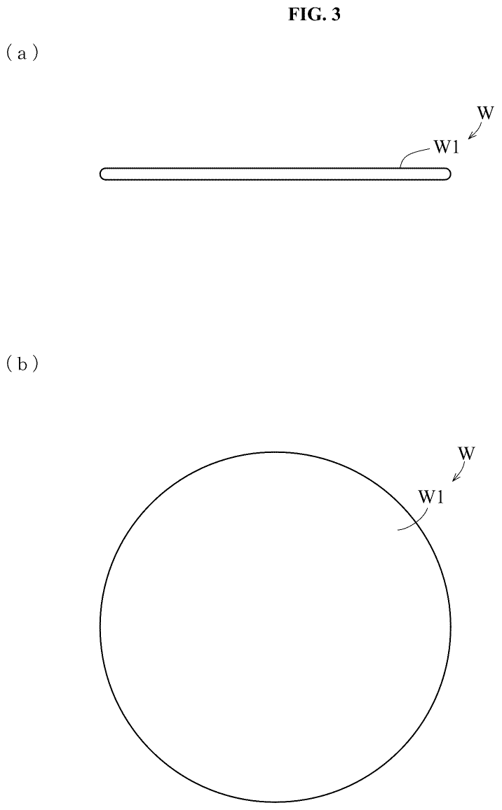

FIG. 3(a) is a side view of the substrate W. FIG. 3(b) is a plan view of the substrate W. The substrate W has a thin flat plate shape. The substrate W has a substantially circular shape in plan view.

Specifically, the substrate W has a first surface W1. The first surface W1 has a substantially circular shape in plan view. The first surface W1 is substantially a flat surface. The first surface W1 is substantially flat.

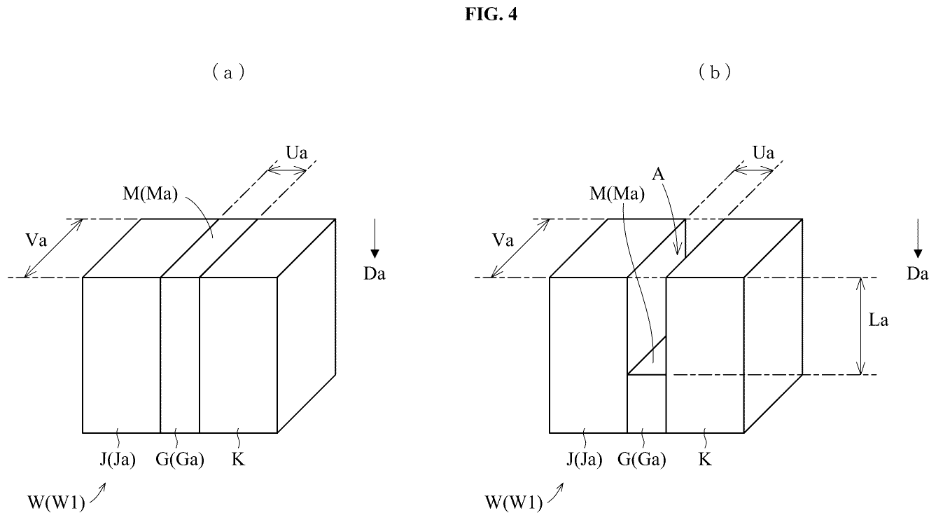

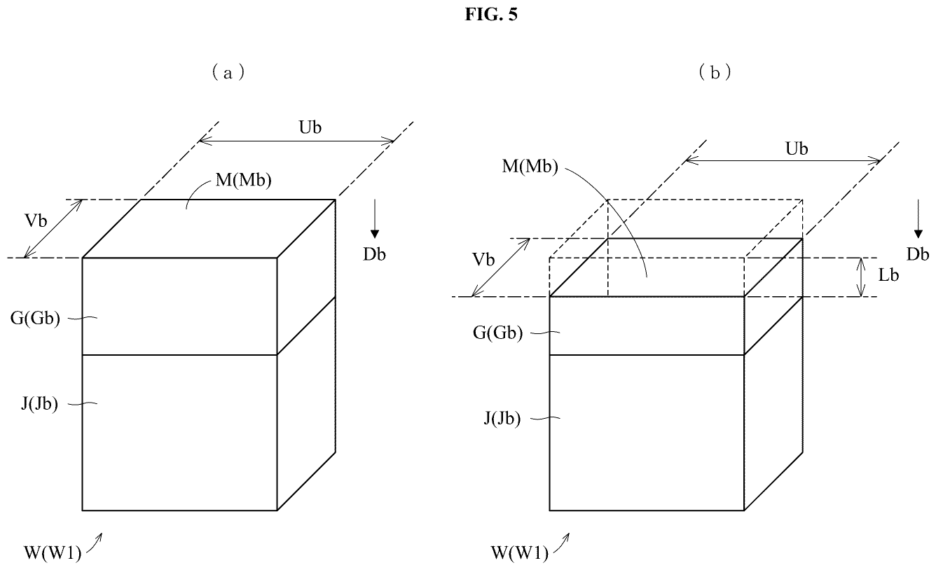

FIGS. 4(a), 4(b), 5(a), and 5(b) are detailed diagrams of a part of the substrate W, respectively. The substrate W includes the first layer G. The first layer G is located on the first surface W1.

The first layer G contains, for example, silicon oxide. The first layer G is made of, for example, silicon oxide. The silicon oxide contains, for example, silicon dioxide (SiO₂). The silicon oxide contains, for example, silicon suboxide (SiOx, 0<x<2). Silicon suboxide is suboxide for silicon dioxide. Silicon suboxide is also referred to as lower silicon oxide. The silicon suboxide contains, for example, silicon monoxide (SiO).

The first layer G may have a film shape. The first layer G may have a plate shape. The first layer G is, for example, a silicon oxide film. The first layer G is, for example, a thermal oxide film.

The first layer G is, for example, an interlayer film Ga. The first layer G is, for example, a blanket film Gb.

Refer to FIGS. 4(a) and 4(b). The interlayer film Ga will be described. The substrate W further includes a second layer Ja and a third layer K. Each of the second layer Ja and the third layer K is located on the first surface W1. The second layer Ja, the interlayer film Ga, and the third layer K are stacked on each other. The second layer Ja, the interlayer film Ga, and the third layer K are stacked in this order. The second layer Ja is in contact with the interlayer film Ga. The third layer K is in contact with the interlayer film Ga. The interlayer film Ga is disposed between the second layer Ja and the third layer K.

The interlayer film Ga has a surface Ma. The surface Ma is exposed. The surface Ma is disposed between the second layer Ja and the third layer K. The surface Ma is in contact with the second layer Ja. The surface Ma is in contact with the third layer K.

The surface Ma has, for example, a first side in contact with the second layer Ja. The surface Ma has, for example, a second side in contact with the third layer K. The second side faces the first side, for example.

The interlayer film Ga has lengths Ua and Va. The lengths Ua and Va are dimensions of the surface Ma. The length Ua corresponds to the thickness of the interlayer film Ga. The length Ua corresponds to a separation distance between the second layer Ja and the third layer K.

The interlayer film Ga is etched. Specifically, the surface Ma is etched. FIG. 4(a) illustrates the interlayer film Ga before being etched. FIG. 4(b) illustrates the interlayer film Ga after etching. By etching the interlayer film Ga, at least a part of the interlayer film Ga is removed.

The interlayer film Ga is selectively etched. Etching of the second layer Ja is suppressed. Etching of the third layer K is suppressed. As a result, the recess A is formed. The recess A is a space. The recess A is located between the second layer Ja and the third layer K. The length Ua corresponds to the width of the recess A. The second layer Ja, the recess A, and the third layer K constitute a pattern. The pattern has, for example, an uneven shape. The first surface W1 is also referred to as a pattern-formed surface.

The interlayer film Ga is etched in the depth direction Da. The depth direction Da is, for example, perpendicular to the surface Ma. The recess A extends in the depth direction Da. The relationship between the depth direction Da and the first surface W1 is appropriately selected. For example, the depth direction Da may be parallel to the first surface W1. Alternatively, the depth direction Da may be perpendicular to the first surface W1.

FIG. 4(b) illustrates a distance La. The distance La corresponds to the etching amount of the interlayer film Ga in the depth direction Da. The distance La is, for example, a length of the recess A in the depth direction Da.

The interlayer film Ga is, for example, small. The interlayer film Ga is, for example, thin.

Specifically, the length Ua is small. The length Ua is, for example, 50 nm or less. The length Ua is, for example, 20 nm or less. The length Ua is, for example, 10 nm or less. The length Va is appropriately selected. For example, the length Va may be greater than the length Ua. Alternatively, the length Va may be smaller than the length Ua.

The second layer Ja has a composition different from the composition of the interlayer film Ga. For example, the second layer Ja contains at least one of single crystal silicon, polycrystalline silicon, amorphous silicon, and silicon nitride.

The second layer Ja may have, for example, a film shape. The second layer Ja may have, for example, a plate shape. For example, the second layer Ja is a single crystal silicon substrate.

The third layer K has a composition different from the composition of the interlayer film Ga. For example, the third layer K contains at least one of single crystal silicon, polycrystalline silicon, amorphous silicon, and silicon nitride.

The third layer K may have, for example, a film shape. The third layer K may have, for example, a plate shape. For example, the third layer K is a polycrystalline silicon film.

Here, the polycrystalline silicon is also referred to as polysilicon.

Refer to FIGS. 5(a) and 5(b). The blanket film Gb will be described. The blanket film Gb has a surface Mb. The surface Mb is exposed. The surface Mb is not in contact with a solid other than the blanket film Gb. The surface Mb is not disposed between solids other than the blanket film Gb. The surface Mb is not sandwiched by a solid other than the blanket film Gb. The blanket film Gb is different from the interlayer film Ga in these points.

The substrate W may further include a second layer Jb. The second layer Jb is located on the first surface W1. The blanket film Gb and the second layer Jb are stacked on each other. The blanket film Gb is in contact with the second layer Jb. However, the surface Mb is not in contact with the second layer Jb. The second layer Jb is in contact with a second surface of the blanket film Gb. The second surface of the blanket film Gb is located, for example, on the opposite side of the surface Mb.

The blanket film Gb has lengths Ub and Vb. The lengths Ub and Vb are dimensions of the surface Mb.

The blanket film Gb is etched. Specifically, the surface Mb is etched. FIG. 5(a) illustrates the blanket film Gb before being etched. FIG. 5(b) illustrates the blanket film Gb after being etched. At least a part of the blanket film Gb is removed by etching the blanket film Gb.

The blanket film Gb is selectively etched. Etching of the second layer Jb is suppressed.

The blanket film Gb is etched in a depth direction Db. The depth direction Db is, for example, perpendicular to the surface Mb. The relationship between the depth direction Db and the first surface W1 is appropriately selected. For example, the depth direction Db may be parallel to the first surface W1. Alternatively, the depth direction Db may be perpendicular to the first surface W1.

FIG. 5(b) illustrates a distance Lb. The distance Lb corresponds to the etching amount of the blanket film Gb in the depth direction Db.

The blanket film Gb is large, for example. The blanket film Gb is wide, for example.

Specifically, the lengths Ub and Vb are each large. Each of the lengths Ub and Vb is larger than 500 nm, for example.

The second layer Jb has a composition different from the composition of the blanket film Gb. For example, the second layer J contains at least one of single crystal silicon, polycrystalline silicon, amorphous silicon, and silicon nitride.

The second layer Jb may have, for example, a film shape. The second layer Jb may have, for example, a plate shape. For example, the second layer Jb is a single crystal silicon substrate.

Hereinafter, in a case where the surface Ma and the surface Mb are not distinguished, the surface Ma and the surface Mb are appropriately referred to as a “surface M”. In a case where the second layer Ja and the second layer Jb are not distinguished, the second layer Ja and the second layer Jb are appropriately referred to as a “second layer J”.

### 1-3. Configuration of Processing Unit 11

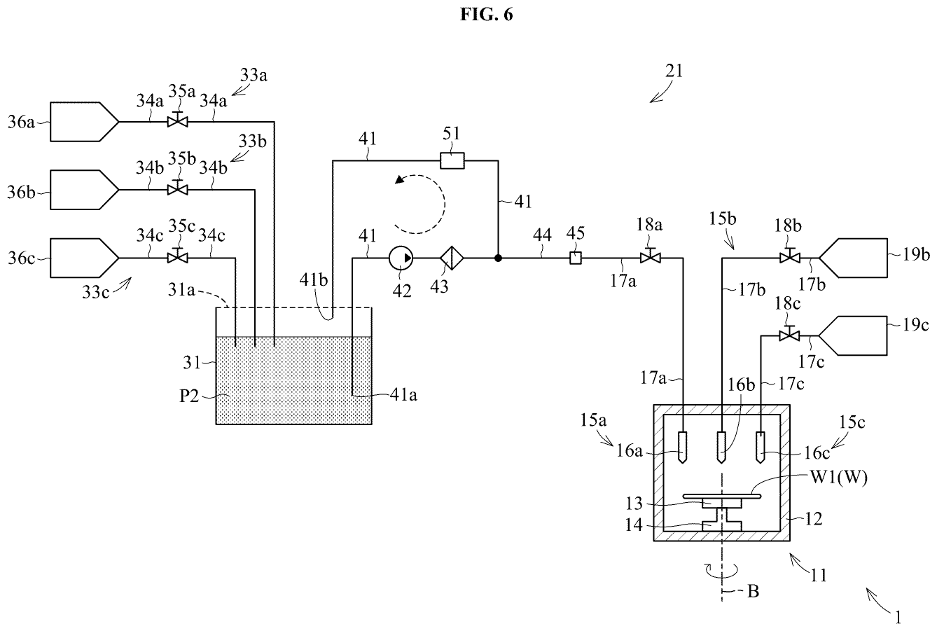

FIG. 6 is a diagram illustrating a configuration of the processing unit 11. Each processing unit 11 has the same structure. The processing unit 11 is classified as a single wafer type. That is, each processing unit 11 processes only one substrate W at a time.

The processing unit 11 includes a housing 12. The housing 12 has a substantially box shape. The substrate holding unit 13 described above is installed inside the housing 12. The substrate W is processed inside the housing 12.

The substrate holding unit 13 holds one substrate W. The substrate holding unit 13 holds the substrate W in a substantially horizontal posture. When the substrate W is held by the substrate holding unit 13, the first surface W1 is horizontal.

When the substrate W is held by the substrate holding unit 13, the first surface W1 faces upward. When the substrate W is held by the substrate holding unit 13, the first surface W1 corresponds to the upper surface of the substrate W. The substrate holding unit 13 is in contact with at least one of the lower surface of the substrate W and the peripheral portion of the substrate W. The lower surface of the substrate W is also referred to as a back side of the substrate W. The substrate holding unit 13 is located below the substrate W held by the substrate holding unit 13. The substrate holding unit 13 is not in contact with the first surface W1.

The processing unit 11 includes a rotation driving unit 14. At least a part of the rotation driving unit 14 is installed inside the housing 12. The rotation driving unit 14 is connected to the substrate holding unit 13. The rotation driving unit 14 rotates the substrate holding unit 13. The substrate W held by the substrate holding unit 13 rotates integrally with the substrate holding unit 13. The substrate W held by the substrate holding unit 13 rotates, for example, about the rotation axis B. The rotation axis B passes through the center of the substrate W, for example. The rotation axis B extends, for example, in the vertical direction Z.

The processing unit 11 includes a supply unit 15a. The supply unit 15a supplies a mixed liquid P2 to the substrate W. The supply unit 15a supplies the mixed liquid P2 to the substrate W held by the substrate holding unit 13. The supply unit 15a supplies the mixed liquid P2 to the first surface W1 of the substrate W held by the substrate holding unit 13.

The supply unit 15a of the first embodiment is an example of a third supply unit in the present invention. The mixed liquid P2 of the first embodiment is an example of the second mixed liquid in the present invention.

Hereinafter, the mixed liquid P2 is appropriately referred to as a “second mixed liquid P2”.

The processing unit 11 includes a supply unit 15b. The supply unit 15b supplies a rinse solution to the substrate W. The supply unit 15b supplies the rinse solution to the substrate W held by the substrate holding unit 13. The rinse solution is, for example, deionized water (DIW).

The processing unit 11 includes a supply unit 15c. The supply unit 15c supplies dry gas to the substrate W. The supply unit 15c supplies dry gas to the substrate W held by the substrate holding unit 13. The dry gas preferably has a dew point lower than the temperature in the housing 12. The dry gas includes at least one of air and an inert gas. The air is, for example, compressed air. The inert gas is, for example, nitrogen gas.

The configurations of the supply units 15a, 15b, and 15c will be exemplified. The supply unit 15a includes a nozzle 16a. The nozzle 16a is installed inside the housing 12. The nozzle 16a is disposed above the substrate W held by the substrate holding unit 13. The nozzle 16a dispenses the second mixed liquid P2. Similarly, the supply units 15b and 15c include nozzles 16b and 16c, respectively. Each of the nozzles 16b and 16c is installed inside the housing 12. The nozzle 16b dispenses the rinse solution. The nozzle 16c dispenses the dry gas.

The supply unit 15a includes a pipe 17a and a valve 18a. The pipe 17a is connected to the nozzle 16a. At least a part of the pipe 17a may be provided outside the housing 12. The valve 18a is provided on the pipe 17a. The valve 18a may be provided outside the housing 12. When the valve 18a is opened, the nozzle 16a dispenses the second mixed liquid P2. When the valve 18a is closed, the nozzle 16a does not dispense the second mixed liquid P2. Similarly, the supply units 15b and 15c include pipes 17b and 17c and valves 18b and 18c, respectively. The pipes 17b and 17c are connected to the nozzles 16b and 16c, respectively. The valves 18b and 18c are provided on the pipes 17b and 17c, respectively. The valve 18b controls the dispensing of the rinse solution by the nozzle 16b. The valve 18c controls the dispensing of the dry gas by the nozzle 16c.

The substrate processing apparatus 1 includes a first adjustment unit 21. The first adjustment unit 21 is connected to the supply unit 15a. The first adjustment unit 21 sends the second mixed liquid P2 to the supply unit 15a.

The supply unit 15b is connected to a supply source 19b. The supply source 19b sends the rinse solution to the supply unit 15b. The supply unit 15c is connected to a supply source 19c. The supply source 19c sends the dry gas to the supply unit 15c.

The first adjustment unit 21 is provided outside the housing 12. Similarly, each of the supply sources 19b and 19c is provided outside the housing 12.

The first adjustment unit 21 may supply the second mixed liquid P2 to the plurality of processing units 11. Alternatively, the first adjustment unit 21 may supply the second mixed liquid P2 to only one processing unit 11. The same applies to the supply sources 19b and 19c.

The supply source 19b may be an element of the substrate processing apparatus 1. For example, the supply source 19b may be installed inside the substrate processing apparatus 1. Alternatively, the supply source 19b may not be an element of the substrate processing apparatus 1. For example, the supply source 19b may be installed outside the substrate processing apparatus 1. Similarly, the supply source 19c may be an element of the substrate processing apparatus 1. Alternatively, the supply source 19c may not be an element of the substrate processing apparatus 1.

The processing unit 11 may further include a cup (not illustrated). The cup is installed inside the housing 12. The cup is disposed laterally of the substrate holding unit 13. The cup surrounds the substrate holding unit 13. The cup receives liquid scattered from the substrate W held by the substrate holding unit 13.

Refer to FIG. 2. The control unit 10 controls the rotation driving unit 14. The control unit 10 controls the supply units 15a to 15c. The control unit 10 controls the valves 18a to 18c.

The control unit 10 is communicably connected to the first adjustment unit 21. The control unit 10 controls the first adjustment unit 21.

### 1-4. Configuration of First Adjustment Unit 21

Refer to FIG. 6. The first adjustment unit 21 includes the tank 31. The tank 31 stores the second mixed liquid P2.

The tank 31 is a container opened to the atmosphere. The tank 31 is opened to air.

For example, the tank 31 has an opening 31a. The opening 31a is disposed in an upper portion of the tank 31. The inside of the tank 31 is opened to the outside of the tank 31 through the opening 31a.

The first adjustment unit 21 includes a supply unit 33a. The supply unit 33a supplies the etching liquid to the tank 31.

The etching liquid contains hydrogen fluoride. In other words, the etching liquid contains a hydrogen fluoride compound. The etching liquid contains, for example, at least one of hydrofluoric acid, dilute hydrofluoric acid (DHF), and buffered hydrofluoric acid (BHF).

The first adjustment unit 21 includes a supply unit 33b. The supply unit 33b supplies iodide to the tank 31.

Iodide is a compound of iodine with an oxidation number of −1. The iodide releases the iodide ions (I⁻). The iodide ion (I⁻) is a monovalent monoatomic anion composed of one iodine atom. The iodide includes, for example, at least one of the following listed compounds a1) to a6).
a1) Tetramethylammonium iodide (TMAI)
a2) Tetraethylammonium iodide (TEAI)
a3) Tetrapropylammonium iodide (TPAI)
a4) Tetrabutylammonium iodide
a5) Ammonium iodide
a6) Hydrogen iodide

The supply unit 33b may supply, for example, a solution containing iodide. The solution is obtained by adding iodide to a solvent. The solvent dissolves the iodide. The solvent is, for example, deionized water (DIW).

The first adjustment unit 21 includes a supply unit 33c. The supply unit 33c supplies deionized water (DIW) to the tank 31.

The second mixed liquid P2 is obtained by adding iodide to the etching liquid. The second mixed liquid P2 may further contain pure water.

The configurations of the supply units 33a, 33b, and 33c will be exemplified. The supply unit 33a includes a pipe 34a and a valve 35a. The pipe 34a is connected to the tank 31. The valve 35a is provided on the pipe 34a. When the valve 35a is opened, the supply unit 33a supplies the etching liquid to the tank 31. When the valve 35a is closed, the supply unit 33a does not supply the etching liquid to the tank 31. Similarly, the supply units 33b and 33c include pipes 34b and 34c and valves 35b and 35c, respectively. Each of the pipes 34b and 34c is connected to the tank 31. The valves 35b and 35c are provided on the pipes 34b and 34c, respectively. The valve 35b controls the supply of iodide to the tank 31. The valve 35c controls the supply of deionized water to the tank 31.

The supply units 33a, 33b, and 33c are connected to the supply sources 36a, 36b, and 36c, respectively. The supply source 36a sends the etching liquid to the supply unit 33a. The supply source 36b sends the iodide to the supply unit 33b. The supply source 36b may send a solution containing iodide to the supply unit 33b. The supply source 36c sends deionized water to the supply unit 33c.

The first adjustment unit 21 includes a circulation pipe 41, a pump 42, and a filter 43. The circulation pipe 41 is connected to the tank 31. Specifically, the circulation pipe 41 has a first end 41a and a second end 41b. Both the first end 41a and the second end 41b are connected to the tank 31. The pump 42 is provided on the circulation pipe 41. The filter 43 is provided on the circulation pipe 41. The filter 43 filters the second mixed liquid P2. The filter 43 removes foreign substances from the second mixed liquid P2.

The first adjustment unit 21 includes a first sensor 51. The first sensor 51 is provided on the circulation pipe 41. The first sensor 51 detects the concentration of the etching liquid in the second mixed liquid P2. For example, the first sensor 51 detects the hydrogen ion concentration of the second mixed liquid P2. For example, the first sensor 51 detects the hydrogen ion exponent (pH) of the second mixed liquid P2. The first sensor 51 is, for example, a pH meter.

The first adjustment unit 21 includes a pipe 44 and a joint 45. The pipe 44 is connected to the circulation pipe 41. The pipe 44 branches from the circulation pipe 41. The joint 45 is connected to the pipe 44. The joint 45 is further connected to the pipe 17a. The tank 31 is connected to the supply unit 15a via the circulation pipe 41 and the pipe 44.

When the valve 18a is closed, the first adjustment unit 21 does not send the second mixed liquid P2 to the supply unit 15a. When the valve 18a is closed and the pump 42 is operated, the second mixed liquid P2 circulates between the tank 31 and the circulation pipe 41. Specifically, the second mixed liquid P2 flows from the tank 31 to the circulation pipe 41 through the first end 41a. Thereafter, the second mixed liquid P2 flows from the first end 41a to the second end 41b through the circulation pipe 41. Thereafter, the second mixed liquid P2 flows from the circulation pipe 41 to the tank 31 through the second end 41b.

When the valve 18a is opened and the pump 42 is operated, the first adjustment unit 21 sends the second mixed liquid P2 to the supply unit 15a. When the valve 18a is opened and the pump 42 is operated, the second mixed liquid P2 flows from the tank 31 to the supply unit 15a.

Refer to FIG. 2. The control unit 10 acquires a detection result of the first sensor 51. The control unit 10 controls the supply units 33a, 33b, and 33c. The control unit 10 controls the valves 35a, 35b, and 35c. The control unit 10 controls the pump 42.

The control unit 10 has processing liquid condition information. The processing liquid condition information defines a condition related to the operation of the first adjustment unit 21. The processing liquid condition information is stored in advance in the storage medium of the control unit 10.

### 1-5. Operation Example of First Adjustment Unit 21 and Processing Unit 11

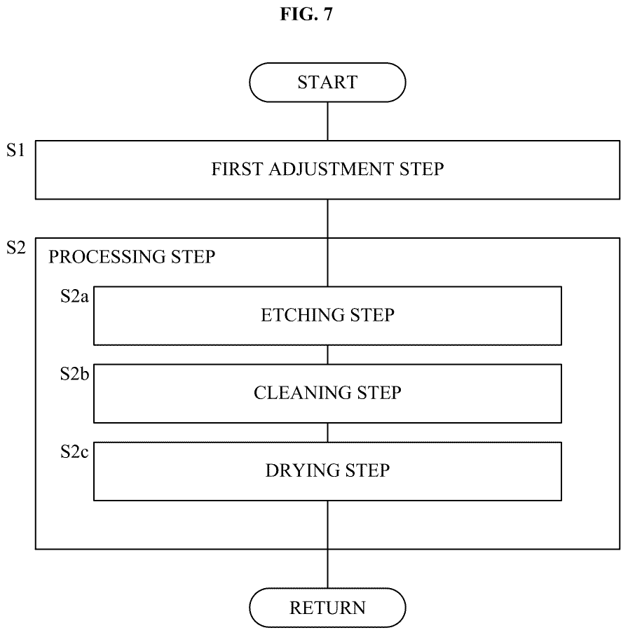

Refer to FIGS. 6 and 7. FIG. 7 is a flowchart illustrating a procedure of the substrate processing method of the first embodiment. The substrate processing method includes a first adjustment step and a processing step. In the first adjustment step and the processing step, the control unit 10 controls the processing unit 11 and the first adjustment unit 21 on the basis of the processing liquid condition information and the processing condition information. Each element of the processing unit 11 and the first adjustment unit 21 operates under the control of the control unit 10.

### Step S1: First Adjustment Step

In the first adjustment step, the first adjustment unit 21 generates the second mixed liquid P2.

More specifically, the supply unit 33a supplies the etching liquid to the tank 31. The supply unit 33b supplies the iodide to the tank 31. As a result, the second mixed liquid P2 is generated in the tank 31. The second mixed liquid P2 contains the etching liquid and the iodide. The iodide releases iodide ions (I⁻) into the second mixed liquid P2. Therefore, the second mixed liquid P2 contains the etching liquid and the iodide ions (I⁻). The tank 31 stores the second mixed liquid P2.

Furthermore, in the first adjustment step, the first adjustment unit 21 adjusts the second mixed liquid P2. For example, in the first adjustment step, the first adjustment unit 21 adds oxygen to the second mixed liquid P2.

Specifically, in the first adjustment step, the second mixed liquid P2 is stored in the tank 31 for a predetermined time or more. The second mixed liquid P2 is left in the tank 31 for a predetermined time or more. The second mixed liquid P2 is exposed to air for a predetermined time or more. This is because the tank 31 is opened to air.

In the first adjustment step, the second mixed liquid P2 in the tank 31 takes in oxygen in the air. Oxygen in the air is dissolved in the second mixed liquid P2 in the tank 31. Oxygen in the air changes to dissolved oxygen in the second mixed liquid P2. That is, oxygen is added to the second mixed liquid P2.

The amount of oxygen in the second mixed liquid P2 increases. The amount of oxygen in the second mixed liquid P2 becomes, for example, 5 ppm or more. The amount of oxygen in the second mixed liquid P2 becomes, for example, 8 ppm or more. The amount of oxygen in the second mixed liquid P2 reaches, for example, the saturated amount of dissolved oxygen. The second mixed liquid P2 is rich in oxygen.

Oxygen in the second mixed liquid P2 oxidizes the iodide ions (I⁻) in the second mixed liquid P2. For example, as shown in the following chemical reaction formula, the iodide ions (I⁻) change to molecular iodine (I₂).

2I⁻→I₂+2e⁻

For example, as shown in the following chemical reaction formula, the iodide ions (I⁻) change to triiodide ions (I₃⁻).

The triiodide ion (I₃⁻) is a monovalent polyatomic anion composed of three iodine atoms.

I⁻+I₂→I₃⁻

Therefore, at least one of the amount of the molecular iodine (I₂) in the second mixed liquid P2 and the amount of the triiodide ions (I₃⁻) in the second mixed liquid P2 increases. That is, at least one of the content of the molecular iodine (I₂) in the second mixed liquid P2 and the content of the triiodide ions (I₃⁻) in the second mixed liquid P2 becomes high. As a result, the second mixed liquid P2 is rich in at least one of the molecular iodine (I₂) and the triiodide ions (I₃⁻).

The time during which the second mixed liquid P2 is exposed to air is referred to as an air exposure time. The air exposure time is, for example, a time during which the second mixed liquid P2 is stored in the tank 31. For example, when the second mixed liquid P2 is generated in the tank 31, the air exposure time starts. For example, the air exposure time begins when iodide is supplied to the tank 31. For example, when the second mixed liquid P2 is sent from the tank 31 to the supply unit 15a, the air exposure time ends.

The air exposure time is equal to or longer than a predetermined time. The first adjustment step is continued until the air exposure time reaches the predetermined time or more. After the air exposure time becomes equal to or longer than the predetermined time, the first adjustment step is appropriately ended.

As a result, the second mixed liquid P2 exposed to the air for the predetermined time or more is obtained. That is, the second mixed liquid P2 adjusted in the first adjustment step is obtained.

The predetermined time described above is determined on the basis of, for example, an experiment or simulation. The predetermined time is set in the processing liquid condition information, for example.

In the first adjustment step, the valve 18a is closed. In the first adjustment step, the pump 42 is appropriately operated. The second mixed liquid P2 flows through the circulation pipe 41. The filter 43 filters the second mixed liquid P2. The first sensor 51 detects the concentration of the etching liquid in the second mixed liquid P2. The control unit 10 acquires a detection result of the first sensor 51.

For example, when a part of the second mixed liquid P2 evaporates, the concentration of the etching liquid in the second mixed liquid P2 may vary. The control unit 10 monitors the concentration of the etching liquid in the second mixed liquid P2 on the basis of the detection result of the first sensor 51. The control unit 10 controls the supply units 33a and 33c on the basis of the detection result of the first sensor 51. As a result, the control unit 10 adjusts the concentration of the etching liquid in the second mixed liquid P2.

For example, when the concentration of the etching liquid in the second mixed liquid P2 is lower than a first range, the supply unit 33a additionally supplies the etching liquid to the tank 31. As a result, the concentration of the etching liquid in the second mixed liquid P2 increases. When the concentration of the etching liquid in the second mixed liquid P2 falls within the first range, the supply unit 33a stops the additional supply of the etching liquid to the tank 31.

For example, when the concentration of the etching liquid in the second mixed liquid P2 is higher than the first range, the supply unit 33c supplies deionized water to the tank 31. As a result, the concentration of the etching liquid in the second mixed liquid P2 decreases. When the concentration of the etching liquid in the second mixed liquid P2 falls within the first range, the supply unit 33c stops the additional supply of deionized water to the tank 31.

As a result, the concentration of the etching liquid in the second mixed liquid P2 is adjusted to the first range.

The first range is set in the processing liquid condition information, for example.

### Step S2: Processing Step

The processing step includes an etching step, a cleaning step, and a drying step. The etching step, the cleaning step, and the drying step are performed in this order.

In the etching step, the cleaning step, and the drying step, the substrate holding unit 13 holds the substrate W. In the etching step, the cleaning step, and the drying step, the rotation driving unit 14 rotates the substrate W held by the substrate holding unit 13.

### Step S2a: Etching Step

After the end of the first adjustment step, the etching step is executed. In the etching step, the first adjustment unit 21 sends the second mixed liquid P2 adjusted in the first adjustment step to the supply unit 15a. In the etching step, the supply unit 15a supplies the second mixed liquid P2 adjusted in the first adjustment step to the substrate W held by the substrate holding unit 13.

The first surface W1 is exposed to the second mixed liquid P2 adjusted in the first adjustment step. The first layer G is exposed to the second mixed liquid P2 adjusted in the first adjustment step. The surface M is exposed to the second mixed liquid P2 adjusted in the first adjustment step. The first layer G is etched.

When the first layer G includes the interlayer film Ga, the interlayer film Ga is selectively etched. That is, the interlayer film Ga is etched while the etching of the second layer Ja and the third layer K is suppressed.

### Step S2b: Cleaning Step

In the cleaning step, the supply unit 15b supplies the rinse solution to the substrate W held by the substrate holding unit 13. The substrate W is cleaned with the rinse solution. The second mixed liquid P2 is removed from the substrate W.

### Step S2c: Drying Step

In the drying step, the supply unit 15c supplies dry gas to the substrate W held by the substrate holding unit 13. The substrate W is dried with the dry gas. The rinse solution is removed from the substrate W.

### 1-6. Technical Significance of First Adjustment Step

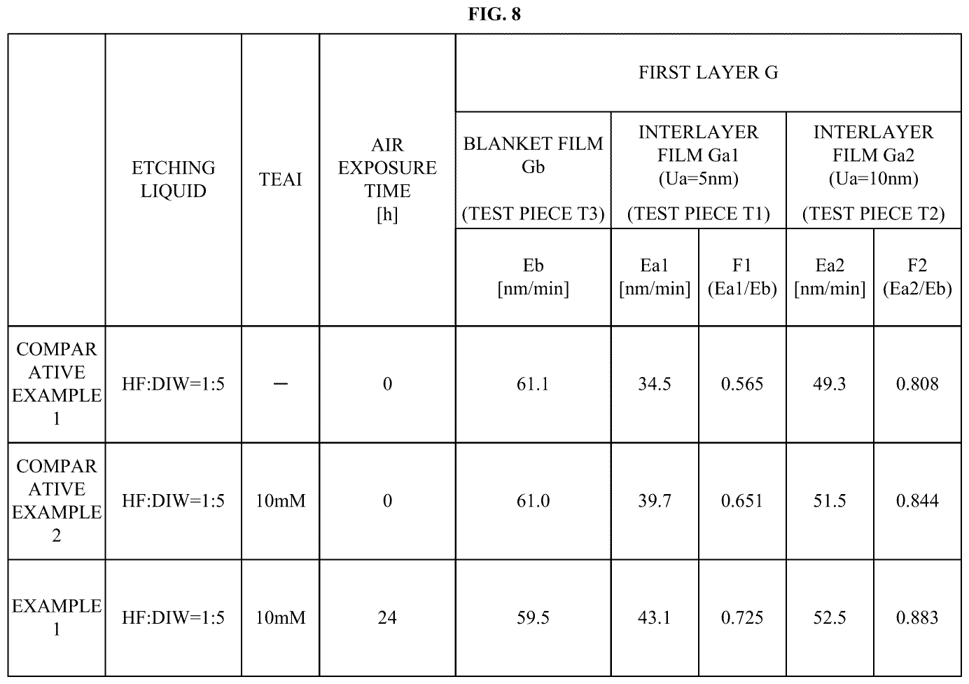

Technical significance of the first adjustment step will be described with reference to Example 1 and Comparative Examples 1 and 2. FIG. 8 is a table showing Example 1 and Comparative Examples 1 and 2.

Conditions of Comparative Example 1 will be described. In Comparative Example 1, an etching liquid is generated. The etching liquid consists of hydrogen fluoride and deionized water. The volume ratio of hydrogen fluoride and deionized water is as follows.

### Hydrogen Fluoride: Deionized Water=1:5 (Volume Ratio)

Note that the etching liquid does not contain molecular iodine (I₂). The etching liquid does not contain triiodide ions (I₃⁻). In Comparative Example 1, the etching liquid is supplied to test pieces T1, T2, and T3 immediately after the etching liquid is generated. That is, in Comparative Example 1, the air exposure time of the etching liquid is 0 hour.

Conditions of Comparative Example 2 will be described. In Comparative Example 2, a mixed liquid consisting of an etching liquid and an iodide is generated.

The etching liquid consists of hydrogen fluoride and deionized water. The volume ratio of hydrogen fluoride and deionized water is as follows.

### Hydrogen Fluoride: Deionized Water=1:5 (Volume Ratio)

The iodide is tetraethylammonium iodide (TEAI). Hereinafter, tetraethylammonium iodide is appropriately referred to as “TEAI”. The concentration of TEAI in the mixed liquid is 10 mM. Here, M means mol/L. That is, in Comparative Example 2, the amount of TEAI per 1 L of the mixed liquid is 0.010 mol. In Comparative Example 2, the mixed liquid is supplied to the test pieces T1, T2, and T3 immediately after the mixed liquid is generated. That is, in Comparative Example 2, the air exposure time of the mixed liquid is 0 hour.

Note that, immediately after generation of the mixed liquid, the mixed liquid is colorless and transparent. Therefore, the content of the molecular iodine (I₂) in the mixed liquid is low immediately after the mixed liquid is generated. Immediately after the mixed liquid is generated, the content of the triiodide ions (I₃) in the mixed liquid is low.

Conditions of the first embodiment will be described. In Example 1, a mixed liquid consisting of an etching liquid and an iodide is generated. The conditions for the generation of the mixed liquid are the same between Example 1 and Comparative Example 2. In Example 1, after the mixed liquid is generated, the mixed liquid is exposed to air for 24 hours. Thereafter, the mixed liquid is supplied to the test pieces T1, T2, and T3. That is, in Example 1, the air exposure time of the mixed liquid is 24 hours.

Note that, after the mixed liquid is exposed to air for 24 hours, the mixed liquid has a yellow color. Therefore, after the mixed liquid is exposed to air for 24 hours, at least one of the content of the molecular iodine (I₂) in the mixed liquid and the triiodide ions (I₃⁻) in the mixed liquid is high.

The test pieces T1, T2, and T3 will be described. Each of the test pieces T1, T2, and T3 simulates the substrate W. The conditions for the test pieces T1, T2, and T3 are common between Example 1 and Comparative Examples 1 and 2. Each of the test pieces T1, T2, and T3 includes the first layer G. The first layer G of the test piece T2 is smaller than the first layer G of the test piece T3. The first layer G of the test piece T1 is smaller than the first layer G of the test piece T2.

For convenience, refer to FIGS. 4(a) and 4(b). The test piece T1 includes an interlayer film Ga as the first layer G. The interlayer film Ga of the test piece T1 is appropriately referred to as an “interlayer film Ga1”. The test piece T1 includes a second layer Ja and a third layer K. The second layer Ja is in contact with the interlayer film Ga1. The third layer K is in contact with the interlayer film Ga1. The interlayer film Ga1 is disposed between the second layer Ja and the third layer K. The surface Ma of the interlayer film Ga1 is in contact with the second layer Ja. The surface Ma of the interlayer film Ga1 is in contact with the third layer K. The interlayer film Ga1 is made of silicon oxide. The second layer Ja is made of single crystal silicon. The third layer K is made of polycrystalline silicon. The length Ua of the interlayer film Gal is 5 nm.

The test piece T2 has a structure similar to that of the test piece T1. That is, the test piece T2 includes the interlayer film Ga, the second layer Ja, and the third layer K. The interlayer film Ga of the test piece T2 is appropriately referred to as an “interlayer film Ga2”. The interlayer film Ga2 is made of silicon oxide. The second layer Ja is made of single crystal silicon. The third layer K is made of polycrystalline silicon. The length Ua of the interlayer film Ga2 is 10 nm.

For convenience, refer to FIGS. 5(a) and 5(b). The test piece T3 includes a blanket film Gb as the first layer G. Further, the test piece T3 includes the second layer Jb. The second layer Jb is in contact with the blanket film Gb. However, the surface Mb of the blanket film Gb is not in contact with the second layer Jb. The surface Mb of the blanket film Gb is not in contact with a solid other than the blanket film Gb. The blanket film Gb is made of silicon oxide. The second layer Jb is made of single crystal silicon. The length Ub of the blanket film Gb is 20 mm. The length Vb of the blanket film Gb is 20 mm.

After the test pieces T1, T2, and T3 are etched in Example 1 and Comparative Examples 1 and 2, the etching rates Ea1, Ea2, and Eb are measured. The etching rate Ea1 is an etching rate of the interlayer film Ga1 of the test piece T1. The etching rate Ea2 is an etching rate of the interlayer film Ga2 of the test piece T2. The etching rate Eb is an etching rate of the blanket film Gb of the test piece T3. Here, the etching rates Ea1 and Ea2 are distances La per minute, respectively. The distance La is illustrated in FIG. 4(b). The etching rate Eb is a distance Lb per minute. The distance Lb is illustrated in FIG. 5(b).

Further, blanket ratios F1 and F2 are calculated. The blanket ratio F1 is a ratio of the etching rate Ea1 to the etching rate Eb. The blanket ratio F2 is a ratio of the etching rate Ea2 to the etching rate Eb. The blanket ratios F1 and F2 are each defined by the following equations:

$$F 1 = Ea 1 / Eb$$

$$F 2 = Ea 2 / Eb$$

Refer to FIG. 8. The etching rate Ea1 of Comparative Example 2 is larger than the etching rate Ea1 of Comparative Example 1. The etching rate Ea1 of Example 1 is higher than the etching rate Ea1 of Comparative Example 2. The etching rate Ea2 of Comparative Example 2 is larger than the etching rate Ea2 of Comparative Example 1. The etching rate Ea2 of Example 1 is higher than the etching rate Ea2 of Comparative Example 2.

From these results, the following can be said. The etching rates Ea1 and Ea2 correspond to the etching rate of the first layer G when the first layer G is small. When the first layer G is small, the mixed liquid of Comparative Example 2 etches the first layer G more efficiently than the etching liquid of Comparative Example 1. When the first layer G is small, the mixed liquid of Example 1 etches the first layer G more efficiently than the mixed liquid of Comparative Example 2.

Refer to FIG. 8. Among the blanket ratio F1 of Example 1, the blanket ratio F1 of Comparative Example 1, and the blanket ratio F1 of Comparative Example 2, the blanket ratio F1 of Example 1 is closest to 1. In other words, the difference between the blanket ratios F1 of Example 1 and 1 is smaller than the difference between the blanket ratios F1 of Comparative Example 1 and 1 and the difference between the blanket ratios F1 of Comparative Example 2 and 1. Among the blanket ratio F2 of Example 1, the blanket ratio F2 of Comparative Example 1, and the blanket ratio F2 of Comparative Example 2, the blanket ratio F2 of Example 1 is closest to 1.

From these results, the following can be said. The etching rate of the first layer G in Example 1 hardly varies regardless of whether the first layer G is the interlayer film Ga or the blanket film Gb. In other words, the mixed liquid of Example 1 suppresses a variation between the etching rate of the first layer G when the first layer G is small and the etching rate of the first layer G when the first layer G is large. That is, regardless of the size of the first layer G, the mixed liquid of Example 1 appropriately etches the first layer G.

### 1-7. Mechanism for Assisting Etching of First Layer G

The present inventors have inferred that at least one of the molecular iodine (I₂) and the triiodide ions (I₃⁻) assists etching of the first layer G. The present inventors infer the mechanism of assisting etching of the first layer G as follows.

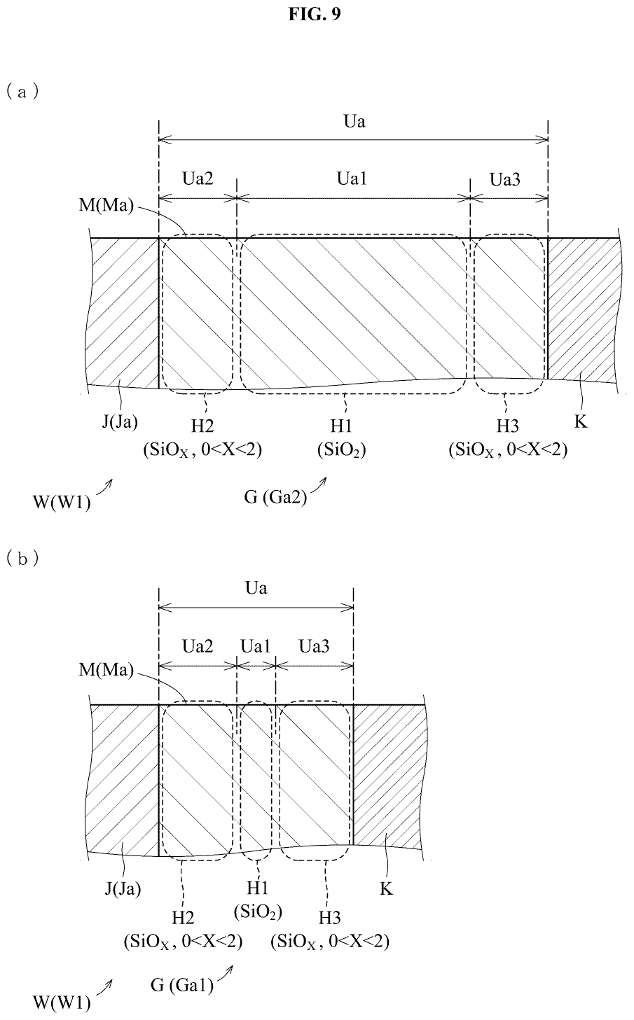

FIGS. 9(a) and 9(b) are diagrams schematically illustrating the first layer G. The first layer G in FIG. 9(a) is, for example, the interlayer film Ga2 of the test piece T2. The first layer G in FIG. 9(b) is, for example, the interlayer film Ga1 of the test piece T1. The first layer G in FIG. 9(b) is smaller than the first layer G in FIG. 9(a). The first layer G in FIG. 9(b) is thinner than the first layer G in FIG. 9(a). The length Ua illustrated in FIG. 9(b) is smaller than the length Ua illustrated in FIG. 9(a).

The first layer G may have a first portion H1, a second portion H2, and a third portion H3. The first portion H1 is made of silicon dioxide (SiO₂). The second portion H2 is made of silicon suboxide (SiOx, 0<X<2). The third portion H3 is made of silicon suboxide (SiOx, 0<X<2).

The second portion H2 is located, for example, near the second layer J. The third portion H3 is located, for example, near the third layer K. The first portion H1 is located, for example, between the second portion H2 and the third portion H3.

The first portion H1 extends to, for example, the surface Ma. The second portion H2 extends to, for example, the surface Ma. The third portion H3 extends to, for example, the surface Ma.

The first portion H1 has a width Ua1. The second portion H2 has a width Ua2. The third portion H3 has a width Ua3. The sum of the width Ua1, the width Ua2, and the width Ua3 is, for example, equal to the length Ua described above. The width Ua2 is, for example, several nm. The width Ua3 is, for example, several nm.

As the first layer G becomes smaller, the first portion H1 becomes smaller. For example, the width Ua1 illustrated in FIG. 9(b) is smaller than the width Ua1 illustrated in FIG. 9(a).

As the first layer G becomes smaller, the proportion of the second portion H2 in the first layer G increases. As the first layer G becomes smaller, the proportion of the third portion H3 in the first layer G increases. Therefore, as the first layer G becomes smaller, the proportion of silicon suboxide in the first layer G increases.

As the first layer G becomes smaller, the proportion of the second portion H2 in the surface Ma increases. As the first layer G becomes smaller, the proportion of the third portion H3 in the surface Ma increases. Therefore, as the first layer G becomes smaller, the proportion of silicon suboxide in the surface Ma increases.

Etching the silicon dioxide is easy. Silicon suboxide is chemically more stable than silicon dioxide. Therefore, it is more difficult to etch silicon suboxide than to etch silicon dioxide.

Therefore, as the proportion of silicon suboxide in the first layer G increases, it becomes more difficult to etch the first layer G only with the etching liquid. As the proportion of the silicon suboxide in the surface Ma increases, it becomes more difficult to etch the first layer G only with the etching liquid. That is, as the first layer G becomes smaller, it becomes more difficult to etch the first layer G only with the etching liquid.

Molecular iodine (I₂) oxidizes silicon suboxide. Triiodide ions (I₃) oxidize silicon suboxide.

For example, as shown in the following chemical reaction formula, molecular iodine (I₂) oxidizes silicon monoxide.

$$SiO + {I}_{2} \to {SiI}_{2} O$$

For example, as shown in the following chemical reaction formula, triiodide ions (I₃⁻) oxidize silicon monoxide.

$$SiO + {I}_{3}^{-} \to {SiI}_{2} O + {I}^{-}$$

Silicon monoxide is converted into compound (SiI₂O). The compound (SiI₂O) is appropriately referred to as “silicon monoxide iodide”.

Silicon monoxide iodide is more chemically unstable than silicon suboxide. Therefore, it is easier to etch silicon monoxide iodide with the etching liquid than to etch silicon suboxide with the etching liquid.

For example, as shown in the following chemical reaction formula, silicon monoxide iodide is etched with the etching liquid.

$$Si {I}_{2} O + 6 HF \to {H}_{2} {SiF}_{6} + {H}_{2} O + 2 HI$$

Therefore, oxidizing the silicon suboxide is equivalent to assisting the etching of the first layer G. Therefore, at least one of the molecular iodine (I₂) and the triiodide ions (I₃⁻) assists the etching of the first layer G. When at least one of the molecular iodine (I₂) and the triiodide ions (I₃⁻) assists the etching of the first layer G, the first layer G is appropriately etched with an etching liquid. That is, the first layer G is appropriately etched with an etching liquid and at least one of the molecular iodine (I₂) and the triiodide ions (I₃⁻). Even when the first layer is small, the first layer G is appropriately etched with an etching liquid and at least one of the molecular iodine (I₂) and the triiodide ions (I₃⁻).

In the above description, at least one of the molecular iodine (I₂) and the triiodide ions (I₃⁻) assists the etching of the interlayer film Ga. However, the present invention is not limited thereto. At least one of the molecular iodine (I₂) and the triiodide ions (I₃⁻) may assist the etching of the blanket film Gb. For example, the blanket film Gb may contain silicon suboxide. For example, the surface Mb of the blanket film Gb may contain silicon suboxide. In these cases, at least one of the molecular iodine (I₂) and the triiodide ions (I₃⁻) assists the etching of the blanket film Gb. Specifically, at least one of the molecular iodine (I₂) and the triiodide ions (I₃⁻) oxidizes silicon suboxide of the blanket film Gb.

### 1-8. Effects of First Embodiment

The substrate processing method of the first embodiment is for processing the substrate W. The substrate W includes the first layer G.

A second mixed liquid P2 contains an etching liquid and iodide ions (I⁻). The substrate processing method of the first embodiment includes the first adjustment step. In the first adjustment step, oxygen is added to the second mixed liquid P2. In the first adjustment step, the iodide ions (I⁻) in the second mixed liquid P2 are oxidized. Specifically, in the first adjustment step, the iodide ions (I⁻) in the second mixed liquid P2 change to at least one of the molecular iodine (I₂) and the triiodide ions (I₃⁻). Therefore, at least one of the amount of the molecular iodine (I₂) in the second mixed liquid P2 and the amount of the triiodide ions (I₃⁻) in the second mixed liquid P2 increases. That is, at least one of the content of the molecular iodine (I₂) in the second mixed liquid P2 and the content of the triiodide ions (I₃⁻) in the second mixed liquid P2 becomes high.

The substrate processing method of the first embodiment includes the etching step. In the etching step, the second mixed liquid P2 adjusted in the first adjustment step is supplied to the substrate W. In the etching step, the first layer G is exposed to the second mixed liquid P2 adjusted in the first adjustment step. The etching liquid etches the first layer G. At least one of the molecular iodine (I₂) and the triiodide ions (I₃⁻) assists the etching of the first layer G. As described above, the second mixed liquid P2 adjusted in the first adjustment step abundantly contains at least one of the molecular iodine (I₂) and the triiodide ions (I₃⁻). Therefore, even when the first layer G is small, the first layer G is appropriately etched in the etching step.

As described above, according to the substrate processing method of the first embodiment, the first layer G can be appropriately etched even when the first layer G is small.

Furthermore, according to the substrate processing method of the first embodiment, the first layer G is appropriately etched regardless of the size of the first layer G.

The oxygen added to the second mixed liquid P2 in the first adjustment step includes oxygen gas. By adding the oxygen gas to the second mixed liquid P2, the iodide ions (I⁻) in the second mixed liquid P2 are easily oxidized. Therefore, it is easy to increase at least one of the amount of the molecular iodine (I₂) in the second mixed liquid P2 and the amount of the triiodide ions (I₃⁻) in the second mixed liquid P2 in the first adjustment step.

In the first adjustment step, the second mixed liquid P2 is exposed to air for a predetermined time or more. Therefore, in the first adjustment step, oxygen is suitably added to the second mixed liquid P2.

The first layer G contains silicon oxide. The etching liquid in the second mixed liquid P2 contains hydrogen fluoride. It is easy to etch silicon oxide with hydrogen fluoride. Therefore, it is easy to etch the first layer G in the etching step.

At least one of the molecular iodine (I₂) and the triiodide ions (I₃⁻) assists etching of silicon oxide. Therefore, even when the first layer G is small, the first layer G is appropriately etched in the etching step.

The substrate W includes the second layer J. The second layer J has a composition different from the composition of the first layer G. Therefore, in the etching step, the etching of the second layer J is suitably suppressed. In the etching step, the first layer G is etched while suppressing the etching of the second layer J.

The second layer J is in contact with the first layer G. Even when the first layer G is in contact with the second layer J, at least one of the molecular iodine (I₂) and the triiodide ions (I₃⁻) assists etching of the first layer G. Therefore, even when the first layer G in contact with the second layer J is small, the first layer G is appropriately etched in the etching step.

The second layer J contains at least one of single crystal silicon, polycrystalline silicon, amorphous silicon, and silicon nitride. It is difficult to etch at least one of single crystal silicon, polycrystalline silicon, amorphous silicon, and silicon nitride with hydrogen fluoride. Therefore, in the etching step, it is easy to etch the first layer G while suppressing the etching of the second layer J.

Even when the first layer G is in contact with the second layer J, at least one of the molecular iodine (I₂) and the triiodide ions (I₃⁻) assists the etching of the silicon oxide of the first layer G. Therefore, even when the first layer G in contact with the second layer J is small, the first layer G is appropriately etched in the etching step.

The substrate W includes the third layer K. The third layer K has a composition different from the composition of the first layer G. Therefore, etching of the third layer K is suitably suppressed in the etching step. In the etching step, the first layer G is etched while suppressing the etching of the third layer K.

The third layer K is in contact with the first layer G. Even when the first layer G is in contact with the second layer J and the third layer K, at least one of the molecular iodine (I₂) and the triiodide ions (I₃⁻) assists etching of the first layer G. Therefore, even when the first layer G in contact with the second layer J and the third layer K is small, the first layer G is appropriately etched in the etching step.

The third layer K contains at least one of single crystal silicon, polycrystalline silicon, amorphous silicon, and silicon nitride. The etching liquid contains hydrogen fluoride. It is difficult to etch at least one of single crystal silicon, polycrystalline silicon, amorphous silicon, and silicon nitride with hydrogen fluoride. Therefore, in the etching step, it is easy to etch the first layer G while suppressing the etching of the third layer K.

Even when the first layer G is in contact with the third layer K, at least one of the molecular iodine (I₂) and the triiodide ions (I₃⁻) assists the etching of the silicon oxide of the first layer G. Therefore, even when the first layer G in contact with the third layer K is small, the first layer G is appropriately etched in the etching step.

The substrate processing apparatus 1 of the first embodiment processes the substrate W. The substrate W includes the first layer G.

A second mixed liquid P2 contains an etching liquid and iodide ions (I⁻). The substrate processing apparatus 1 of the first embodiment includes the first adjustment unit 21. The first adjustment unit 21 adds oxygen to the second mixed liquid P2. The iodide ions (I⁻) in the second mixed liquid P2 are oxidized. Specifically, the iodide ions (I⁻) in the second mixed liquid P2 change to at least one of the molecular iodine (I₂) and the triiodide ions (I₃⁻). Therefore, at least one of the amount of the molecular iodine (I₂) in the second mixed liquid P2 and the amount of the triiodide ions (I₃⁻) in the second mixed liquid P2 increases. That is, at least one of the content of the molecular iodine (I₂) in the second mixed liquid P2 and the content of the triiodide ions (I₃⁻) in the second mixed liquid P2 becomes high.

The substrate processing apparatus 1 of the first embodiment includes the supply unit 15a. The supply unit 15a supplies the second mixed liquid P2 adjusted by the first adjustment unit 21 to the substrate W. The first layer G is exposed to the second mixed liquid P2 adjusted by the first adjustment unit 21. The etching liquid etches the first layer G. At least one of the molecular iodine (I₂) and the triiodide ions (I₃⁻) assists the etching of the first layer G. As described above, the second mixed liquid P2 adjusted by the first adjustment unit 21 abundantly contains at least one of the molecular iodine (I₂) and the triiodide ions (I₃⁻). Therefore, even when the first layer G is small, the first layer G is appropriately etched.

As described above, according to the substrate processing apparatus 1 of the first embodiment, the first layer G can be appropriately etched even when the first layer G is small.

The first adjustment unit 21 includes the tank 31. The tank 31 stores the second mixed liquid P2. The tank 31 is opened to air. The first adjustment unit 21 stores the second mixed liquid P2 in the tank 31 for a predetermined time or more to add oxygen to the second mixed liquid P2. Therefore, the configuration of the first adjustment unit 21 is simple.

As described above, the tank 31 stores the second mixed liquid P2. That is, the etching liquid and the iodide ions (I⁻) are stored in the same tank (that is, the tank 31). The etching liquid and at least one of the molecular iodine (I₂) and the triiodide ions (I₃⁻) are stored in the same tank (that is, the tank 31). Therefore, the configuration of the first adjustment unit 21 is simple.

### 2. Second Embodiment

A substrate processing apparatus 1 of a second embodiment will be described with reference to the drawings. Note that the same components as those of the first embodiment are denoted by the same reference numerals, and a detailed description thereof will be omitted.

In the second embodiment, the outline of the substrate processing apparatus 1, the structure of the substrate W, and the configuration of the processing unit 11 are substantially the same as those in the first embodiment. The substrate processing apparatus 1 of the second embodiment includes a second adjustment unit 22 and a supply source 23 instead of the first adjustment unit 21 of the first embodiment.

### 2-1. Configuration of Second Adjustment Unit 22 and Supply Source 23

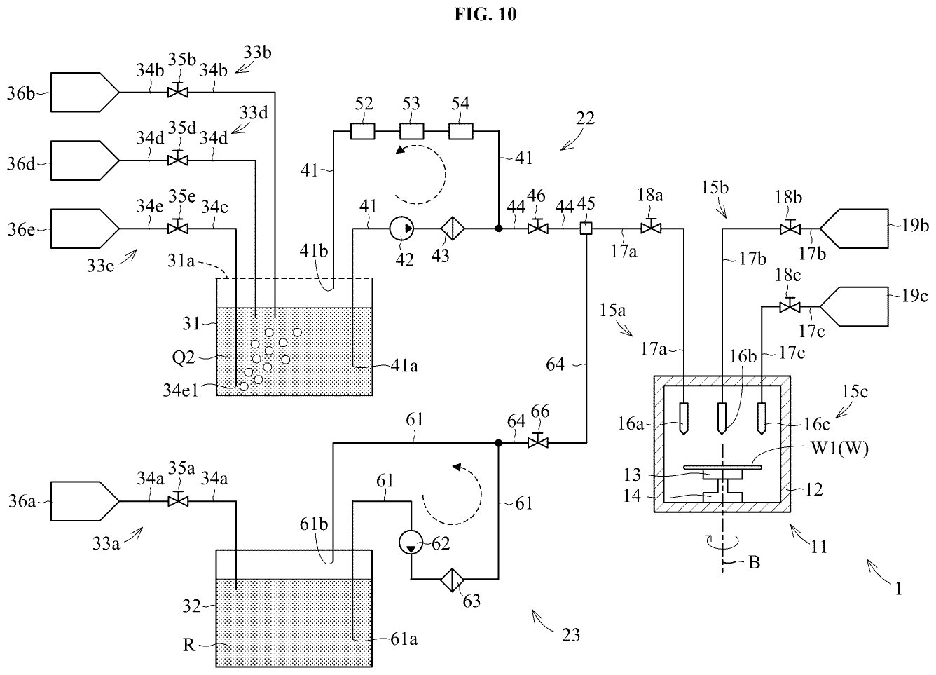

FIG. 10 is a diagram illustrating a configuration of the processing unit 11 and the second adjustment unit 22 of the second embodiment. The second adjustment unit 22 adjusts a solution Q2. For example, the adjustment unit 22 adds oxygen to the solution Q2. The second adjustment unit 22 sends the adjusted solution Q2 to the supply unit 15a. The supply source 23 sends an etching liquid R to the supply unit 15a. The supply unit 15a supplies the solution Q2 adjusted by the second adjustment unit 22 to the substrate W. The supply unit 15a supplies the etching liquid R to the substrate W.

The supply unit 15a of the second embodiment is an example of a fourth supply unit in the present invention. The solution Q2 of the second embodiment is an example of a second solution in the present invention.

Hereinafter, the solution Q2 is appropriately referred to as a “second solution Q2”.

A configuration of the second adjustment unit 22 will be exemplified.

The second adjustment unit 22 includes a tank 31, a supply unit 33b, and a supply unit 33d. The tank 31 stores the second solution Q2. The supply unit 33b supplies iodide to the tank 31. The supply unit 33d supplies a solvent to the tank 31. The solvent dissolves the iodide. The solvent is, for example, deionized water. The second solution Q2 is obtained by adding the iodide to the solvent.

The second adjustment unit 22 includes a supply unit 33e. The supply unit 33e supplies oxygen to the tank 31. The supply unit 33e supplies, for example, oxygen gas into the second solution Q2 in the tank 31.

The configurations of the supply units 33d and 33e will be exemplified. The supply units 33d and 33e include pipes 34d and 34e and valves 35d and 35e, respectively. Each of the pipes 34d and 34e is connected to the tank 31. The valves 35d and 35e are provided on the pipes 34d and 34e, respectively. The valve 35d controls the supply of the solvent to the tank 31. The valve 35e controls the supply of oxygen to the tank 31.

The pipe 34e has a dispensing port 34e1. The dispensing port 34e1 is disposed in the second solution Q2 in the tank 31. The dispensing port 34e1 is immersed in the second solution Q2 in the tank 31.

The supply units 33d and 33e are connected to supply sources 36d and 36e, respectively. The supply source 36d sends the solvent to the supply unit 33d. The supply source 36e sends oxygen to the supply unit 33e.

The second adjustment unit 22 is connected to the supply unit 15a. Specifically, the tank 31 is connected to the supply unit 15a via the circulation pipe 41 and the pipe 44.

The second adjustment unit 22 includes a valve 46. The valve 46 is provided on the pipe 44. The valve 46 controls the amount of the second solution Q2 supplied from the second adjustment unit 22 to the supply unit 15a.

The second adjustment unit 22 includes a second sensor 52, a third sensor 53, and a fourth sensor 54. The second sensor 52, the third sensor 53, and the fourth sensor 54 are provided, for example, on the circulation pipe 41.

The second sensor 52 detects the concentration of iodide ions (I⁻) in the second solution Q2. The second sensor 52 detects the concentration of iodide ions (I⁻) in the second solution Q2 by, for example, absorptiometry. The second sensor 52 is, for example, an ultraviolet absorbance detector or an ultraviolet/visible absorbance detector.

The third sensor 53 detects the concentration of the molecular iodine (I₂) in the second solution Q2. The third sensor 53 detects the concentration of molecular iodine (I₂) in the second solution Q2 by, for example, a colorimetric analysis method. The third sensor 53 is, for example, a colorimeter. The third sensor 53 is, for example, a color difference meter.

The fourth sensor 54 detects the concentration of oxygen in the second solution Q2. The fourth sensor 54 detects the concentration of oxygen in the second solution Q2 by, for example, an electrochemical analysis method (diaphragm electrode method). The fourth sensor 54 is, for example, a dissolved oxygen meter.

A configuration of the supply source 23 will be exemplified.

The supply source 23 includes a tank 32 and a supply unit 33a. The supply unit 33a supplies the etching liquid R to the tank 32. The tank 32 stores the etching liquid R.

The etching liquid R contains hydrogen fluoride. The etching liquid R contains, for example, at least one of hydrofluoric acid, dilute hydrofluoric acid (DHF), and buffered hydrofluoric acid (BHF).

The supply source 23 includes a circulation pipe 61, a pump 62, and a filter 63. The circulation pipe 61 is connected to the tank 32. Specifically, the circulation pipe 61 has a first end 61a and a second end 61b. Both the first end 61a and the second end 61b are connected to the tank 32. The pump 62 is provided on the circulation pipe 41. The filter 63 is provided on the circulation pipe 61. The filter 63 filters the etching liquid R. The filter 63 removes foreign substances from the etching liquid R.

The supply source 23 includes a pipe 64. The pipe 64 is connected to the circulation pipe 61. The pipe 64 branches from the circulation pipe 61. The pipe 64 is further connected to the joint 45. Tank 32 is connected to the supply unit 15a via the circulation pipe 61 and the pipe 64. That is, the supply source 23 is connected to the supply unit 15a.

The supply source 23 includes a valve 66. The valve 66 is provided on the pipe 64. The valve 66 controls the amount of the etching liquid R supplied from the supply source 23 to the supply unit 15a.

Although not illustrated, the control unit 10 controls the second adjustment unit 22 and the supply source 23. The control unit 10 acquires detection results of the second sensor 52, the third sensor 53, and the fourth sensor 54. The control unit 10 controls the supply units 33a, 33b, 33d, and 33e. The control unit 10 controls the valves 35a, 35b, 35d, and 35e. The control unit 10 controls the valves 46 and 66. The control unit 10 controls the pumps 42 and 62.

### 2-2. Example Operation of Second Adjustment Unit 22, Supply Source 23 and Processing Unit 11

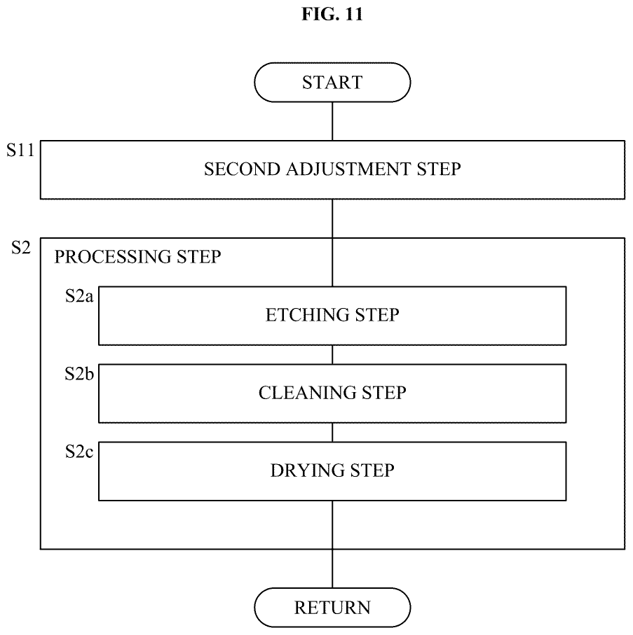

Refer to FIGS. 10 and 11. FIG. 11 is a flowchart illustrating a procedure of a substrate processing method of the second embodiment. The substrate processing method of the second embodiment includes a second adjustment step instead of the first adjustment step of the first embodiment. In the second embodiment, a processing step is executed after the second adjustment step. The operation of the processing step is substantially the same between the first embodiment and the second embodiment. The description of the washing step and the drying step in the processing step will be omitted.

### Step S11: Second Adjustment Step

In the second adjustment step, the second adjustment unit 22 generates the second solution Q2.

More specifically, the supply unit 33b supplies the iodide to the tank 31. The supply unit 33d supplies the solvent to the tank 31. As a result, the second solution Q2 is generated in the tank 31. The second solution Q2 contains an iodide and a solvent. The iodide releases the iodide ions (I⁻) in the second solution Q2. Therefore, the second solution Q2 contains the iodide ions (I⁻). The tank 31 stores the second solution Q2.

In the second adjustment step, the second adjustment unit 22 adjusts the initial concentration of the iodide ions (I⁻) in the second solution Q2. The initial concentration of the iodide ions (I⁻) in the second solution Q2 is the concentration of the iodide ions (I⁻) in the second solution Q2 before the second adjustment unit 22 adjusts the second solution Q2. For example, the initial concentration of iodide ions (I⁻) in the second solution Q2 is the concentration of iodide ions (I⁻) in the second solution Q2 before oxygen is added to the second solution Q2.

Specifically, the supply unit 33e does not supply oxygen to the tank 31. The valve 35e is closed. The second adjustment unit 22 does not supply the second solution Q2 to the supply unit 15a. The valve 46 is closed. The valve 18a is closed. The pump 42 operates. The second solution Q2 flows through the circulation pipe 41. The filter 43 filters the second solution Q2. The second sensor 52 detects the concentration of iodide ions (I⁻) in the second solution Q2. The control unit 10 acquires a detection result of the second sensor 52. The control unit 10 controls the supply units 33b and 33d on the basis of the detection result of the second sensor 52. As a result, the control unit 10 adjusts the initial concentration of the iodide ions (I⁻) in the second solution Q2.

For example, when the initial concentration of the iodide ions (I⁻) in the second solution Q2 is lower than a second range, the supply unit 33b additionally supplies the iodide to the tank 31. As a result, the initial concentration of the iodide ions (I⁻) in the second solution Q2 increases. When the initial concentration of the iodide ions (I⁻) in the second solution Q2 falls within the second range, the supply unit 33b stops the additional supply of the iodide to the tank 31.

For example, when the initial concentration of the iodide ions (I⁻) in the second solution Q2 is higher than the second range, the supply unit 33d supplies the solvent to the tank 31. As a result, the initial concentration of the iodide ions (I⁻) in the second solution Q2 decreases. When the initial concentration of the iodide ions (I⁻) in the second solution Q2 falls within the second range, the supply unit 33d stops the additional supply of the solvent to the tank 31.

As a result, the initial concentration of the iodide ions (I⁻) in the second solution Q2 is adjusted to the second range.

The second range is set in the processing liquid condition information, for example.

Thereafter, the second adjustment unit 22 adjusts the second solution Q2. For example, in the second adjustment step, the second adjustment unit 22 adds oxygen to the second solution Q2.

Specifically, the supply unit 33e supplies oxygen to the tank 31. The valve 35e opens. The supply unit 33e supplies oxygen gas into the second solution Q2 in the tank 31. The supply unit 33e blows oxygen gas into the second solution Q2 in the tank 31. The oxygen gas forms air bubbles in the second solution Q2. FIG. 10 schematically illustrates air bubbles in the second solution Q2. The second solution Q2 is bubbled with the oxygen gas. The supply unit 33e bubbles the second solution Q2 in the tank 31 with oxygen.

A part of the oxygen gas is dissolved in the second solution Q2. A part of the oxygen gas changes to dissolved oxygen in the second solution Q2. That is, oxygen is added to the second solution Q2. The amount of oxygen in the second solution Q2 increases. The second solution Q2 is rich in oxygen.

Oxygen in the second solution Q2 oxidizes the iodide ions (I⁻) in the second solution Q2. For example, the iodide ions (I⁻) change to at least one of molecular iodine (I₂) and triiodide ions (I₃⁻).

The third sensor 53 detects the concentration of the molecular iodine (I₂) in the second solution Q2. The fourth sensor 54 detects the concentration of oxygen in the second solution Q2. The control unit 10 acquires detection results of the third sensor 53 and the fourth sensor 54. The control unit 10 monitors the concentration of the molecular iodine (I₂) in the second solution Q2 on the basis of the detection result of the third sensor 53. The control unit 10 monitors the concentration of oxygen in the second solution Q2 on the basis of the detection result of the fourth sensor 54. The control unit 10 controls the supply unit 33e on the basis of at least one of the detection result of the third sensor 53 and the detection result of the fourth sensor 54.

For example, when the concentration of the molecular iodine (I₂) in the second solution Q2 is equal to or less than a first reference value, the supply unit 33e continues the supply of oxygen to the second solution Q2. For example, when the concentration of the molecular iodine (I₂) in the second solution Q2 exceeds the first reference value, the supply unit 33e stops the supply of oxygen to the second solution Q2. For example, when the concentration of the molecular iodine (I₂) in the second solution Q2 exceeds the first reference value, the second adjustment step ends. The first reference value is set in the processing liquid condition information, for example.

For example, when the concentration of the oxygen in the second solution Q2 is equal to or less than a second reference value, the supply unit 33e continues the supply of oxygen to the second solution Q2. For example, when the concentration of the oxygen in the second solution Q2 exceeds the second reference value, the supply unit 33e stops the supply of oxygen to the second solution Q2. When the concentration of the oxygen in the second solution Q2 exceeds the second reference value, the second adjustment step ends. The second reference value is set in the processing liquid condition information, for example.

As a result, the second solution Q2 adjusted in the second adjustment step is obtained.

### Step S2a: Etching Step

After the end of the second adjustment step, the etching step is executed. In the etching step, the second adjustment unit 22 sends the second solution Q2 adjusted in the second adjustment step to the supply unit 15a. In the etching step, the supply source 23 sends the etching liquid R to the supply unit 15a. The amount of the second solution Q2 supplied to the supply unit 15a and the amount of the etching liquid R supplied to the supply unit 15a are adjusted by the valves 46 and 66. The second solution Q2 adjusted in the second adjustment step and the etching liquid R may be mixed in the joint 45.

In the etching step, the supply unit 15a supplies the second solution Q2 adjusted in the second adjustment step to the substrate W held by the substrate holding unit 13. In the etching step, the supply unit 15a supplies the etching liquid R to the substrate W held by the substrate holding unit 13.

The first layer G is exposed to the second solution Q2 adjusted in the second adjustment step. The first layer G is exposed to the etching liquid R. The first layer G is etched.

### 2-3. Effects of Second Embodiment

Also in the second embodiment, the same effects as those of the first embodiment are obtained.

The second solution Q2 contains the iodide ions (I⁻). The substrate processing method of the second embodiment includes the second adjustment step. In the second adjustment step, oxygen is added to the second solution Q2. In the second adjustment step, the iodide ions (I⁻) in the second solution Q2 are oxidized. Specifically, in the second adjustment step, the iodide ions (I⁻) in the second solution Q2 change to at least one of the molecular iodine (I₂) and the triiodide ions (I₃⁻). Therefore, at least one of the amount of the molecular iodine (I₂) in the second solution Q2 and the amount of the triiodide ions (I₃⁻) in the second solution Q2 increases. That is, at least one of the content of the molecular iodine (I₂) in the second solution Q2 and the content of the triiodide ions (I₃⁻) in the second solution Q2 becomes high.

The substrate processing method of the second embodiment includes the etching step. In the etching step, the second solution Q2 adjusted in the second adjustment step is supplied to the substrate W. In the etching step, the etching liquid R is supplied to the substrate W. The etching liquid R etches the first layer G. At least one of the molecular iodine (I₂) and the triiodide ions (I₃⁻) assists the etching of the first layer G. As described above, the second solution Q2 adjusted in the second adjustment step abundantly contains at least one of the molecular iodine (I₂) and the triiodide ions (I₃⁻). Therefore, even when the first layer G is small, the first layer G is appropriately etched in the etching step.

As described above, according to the substrate processing method of the second embodiment, the first layer G can be appropriately etched even when the first layer G is small.

The oxygen added to the second solution Q2 in the second adjustment step includes oxygen gas. By adding the oxygen gas to the second solution Q2, the iodide ions (I⁻) in the second solution Q2 are easily oxidized. Therefore, it is easy to increase at least one of the amount of the molecular iodine (I₂) in the second solution Q2 and the amount of the triiodide ions (I₃⁻) in the second solution Q2 in the second adjustment step.

In the second adjustment step, the oxygen gas is supplied into the second solution Q2. In the second adjustment step, the oxygen gas is blown into the second solution Q2. In the second adjustment step, the second solution Q2 is bubbled with oxygen gas. Therefore, in the second adjustment step, oxygen is efficiently added to the second solution Q2. Therefore, the time required for the second adjustment step is short.

In the second adjustment step, the supply of oxygen to the second solution Q2 is controlled on the basis of at least one of the detection result of the concentration of the molecular iodine (I₂) in the second solution Q2 and the detection result of the concentration of oxygen in the second solution Q2. For example, in the second adjustment step, the supply of oxygen to the second solution Q2 is continued or stopped on the basis of at least one of the detection result of the concentration of the molecular iodine (I₂) in the second solution Q2 and the detection result of the concentration of oxygen in the second solution Q2. Therefore, the amount of oxygen for adjusting the second solution Q2 is reduced.

The second adjustment step ends on the basis of at least one of the detection result of the concentration of the molecular iodine (I₂) in the second solution Q2 and the detection result of the concentration of oxygen in the second solution Q2. Therefore, the second adjustment step ends at an appropriate timing.

The substrate processing apparatus 1 of the second embodiment includes the second adjustment unit 22. The second adjustment unit 22 adds oxygen to the second solution Q2. Therefore, at least one of the amount of the molecular iodine (I₂) in the second solution Q2 and the amount of the triiodide ions (I₃⁻) in the second solution Q2 increases.

The supply unit 15a supplies the second solution Q2 adjusted by the second adjustment unit 22 to the substrate W. The supply unit 15a supplies the etching liquid R to the substrate W. The etching liquid R etches the first layer G. At least one of the molecular iodine (I₂) and the triiodide ions (I₃⁻) assists the etching of the first layer G. As described above, the second solution Q2 adjusted by the second adjustment unit 22 abundantly contains at least one of the molecular iodine (I₂) and the triiodide ions (I₃⁻). Therefore, even when the first layer G is small, the first layer G is appropriately etched.

As described above, according to the substrate processing apparatus 1 of the second embodiment, the first layer G can be appropriately etched even when the first layer G is small.

The second adjustment unit 22 includes the tank 31 and the supply unit 33e. The tank 31 stores the second solution Q2. The supply unit 33e supplies oxygen to the tank 31. Therefore, the second adjustment unit 22 efficiently adds oxygen to the second solution Q2.

The tank 31 stores the second solution Q2. The tank 32 stores the etching liquid R. That is, the tank (that is, the tank 31) that stores the second solution Q2 is different from the tank (That is, the tank 32) that stores the etching liquid R. Therefore, the composition of the second solution Q2 in the tank 31 is not affected by the etching liquid R. Therefore, oxygen is suitably added to the second solution Q2 in the tank 31. It is easy to adjust the second solution Q2 in the tank 31. On the other hand, the composition of the etching liquid R in the tank 32 is not affected by the second solution Q2. Therefore, it is easy to manage the composition of the etching liquid R in the tank 32. It is easy to manage the concentration of the etching liquid R in the tank 32.

### 3. Third Embodiment

A substrate processing apparatus 1 of a third embodiment will be described with reference to the drawings. Note that the same components as those of the first and second embodiments are denoted by the same reference numerals, and a detailed description thereof will be omitted.

In the third embodiment, the outline of the substrate processing apparatus 1, the structure of the substrate W, and the configuration of the processing unit 11 are substantially the same as those in the first embodiment. The substrate processing apparatus 1 of the third embodiment includes a first generation unit 24 instead of the first adjustment unit 21 of the first embodiment.

### 3-1. Configuration of First Generation Unit 24

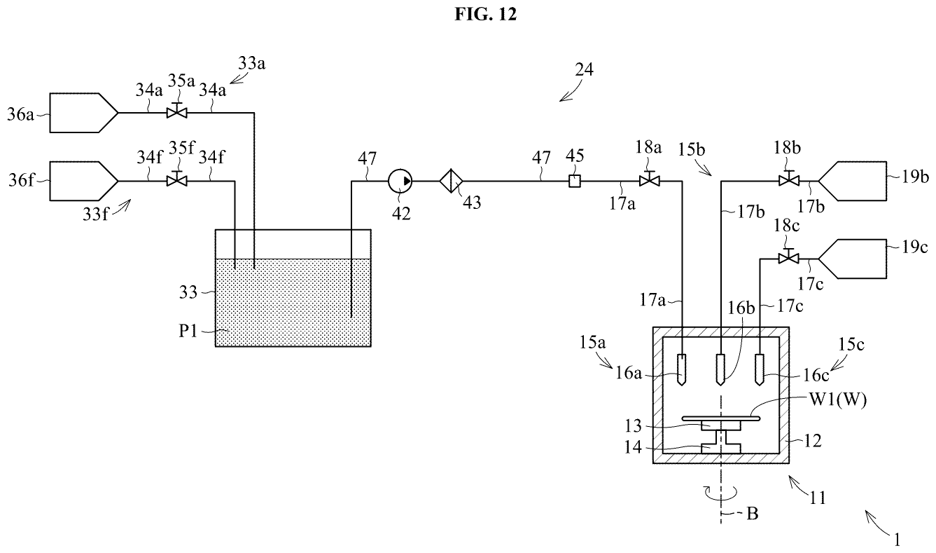

FIG. 12 is a diagram illustrating a configuration of the processing unit 11 and the first generation unit 24 of the third embodiment. The first generation unit 24 generates a mixed liquid P1. The mixed liquid P1 includes an etching liquid. The mixed liquid P1 is obtained by adding at least one of molecular iodine (I₂) and triiodide ions (I₃⁻) to the etching liquid. The first generation unit 24 sends the mixed liquid P1 to the supply unit 15a. The supply unit 15a supplies the mixed liquid P1 to the substrate W.

The supply unit 15a of the third embodiment is an example of a first supply unit in the present invention. The mixed liquid P1 of the third embodiment is an example of a first mixed liquid in the present invention. The mixed liquid P1 of the third embodiment is an example of a substrate processing liquid in the present invention.

Hereinafter, the mixed liquid P1 is appropriately referred to as a “first mixed liquid P1”.

A configuration of the first generation unit 24 will be exemplified.

The first generation unit 24 includes a tank 33. The tank 33 stores the first mixed liquid P1. The tank 33 may be a container that is isolated from the atmosphere. The tank 33 includes, for example, a lid member that closes the upper portion of the tank 33. Alternatively, the tank 33 may be a container that is open to the atmosphere.

The first generation unit 24 includes a supply unit 33a. The supply unit 33a supplies the etching liquid to the tank 33. As described above, the etching liquid contains hydrogen fluoride.

The first generation unit 24 includes a supply unit 33f. The supply unit 33f supplies at least one of molecular iodine (I₂) and triiodide to the tank 33.

Triiodide is a salt containing triiodide ions (I₃⁻). Triiodide is also referred to as “triiodide salt”. Triiodide releases the triiodide ions (I₃⁻). Triiodide includes, for example, at least one of nitrogen triiodide, phosphorus triiodide, and ammonium triiodide.

The supply unit 33f may supply, for example, a solution containing at least one of molecular iodine (I₂) and triiodide. The solution is obtained by adding at least one of molecular iodine (I₂) and triiodide to a solvent. The solvent dissolves molecular iodine (I₂). The solvent dissolves triiodide. The solvent is, for example, deionized water (DIW).

The configuration of the supply unit 33f will be exemplified. The supply unit 33f includes a pipe 34f and a valve 35f. The pipe 34f is connected to the tank 33. The valve 35f is provided on the pipe 34f. The valve 35f controls the supply of at least one of molecular iodine (I₂) and triiodide to the tank 33.

The supply unit 33f is connected to the supply source 36f. The supply source 36f sends at least one of molecular iodine (I₂) and triiodide to the supply unit 33f.

The first generation unit 24 includes a pipe 47 in addition to the pump 42, the filter 43, and the joint 45. The pipe 47 is connected to the tank 33. The pipe 47 is connected to the joint 45. The pump 42 and the filter 43 are provided on the pipe 47. The tank 31 is connected to the supply unit 15a via the pipe 47. That is, the first generation unit 24 is connected to the supply unit 15a.

When the valve 18a is closed, the first adjustment unit 21 does not send the first mixed liquid P1 to the supply unit 15a. When the valve 18a is opened and the pump 42 is operated, the first generation unit 24 sends the first mixed liquid P1 to the supply unit 15a. When the valve 18a is opened and the pump 42 is operated, the first mixed liquid P1 flows from the tank 31 to the supply unit 15a.

Although not illustrated, the control unit 10 controls the first generation unit 24. The control unit 10 controls the supply units 33a and 33f. The control unit 10 controls the valves 35a and 35f. The control unit 10 controls the pump 42.

### 3-2. Operation Example of First Generation Unit 24 and Processing Unit 11

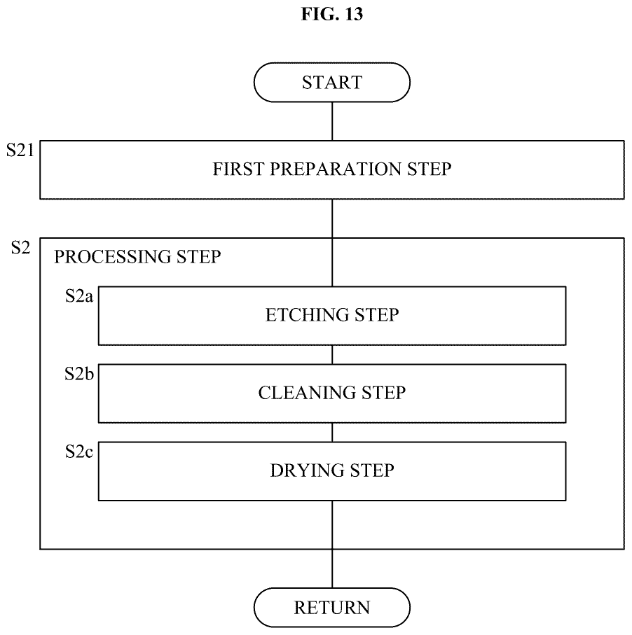

Refer to FIGS. 12 and 13. FIG. 13 is a flowchart illustrating a procedure of a substrate processing method of the third embodiment. The substrate processing method of the third embodiment includes a first preparation step instead of the first adjustment step of the first embodiment. In the third embodiment, a processing step is executed after the first preparation step. The operation of the processing step is substantially the same between the first embodiment and the third embodiment. The description of the washing step and the drying step in the processing step will be omitted.

### Step S21: First Preparation Step

In the first preparation step, the first generation unit 24 prepares the first mixed liquid P1. In the first preparation step, the first generation unit 24 adds at least one of molecular iodine (I₂) and triiodide to the etching liquid.

Specifically, the supply unit 33a supplies the etching liquid to the tank 33. The supply unit 33f supplies at least one of molecular iodine (I₂) and triiodide to the tank 33. As a result, the first mixed liquid P1 is generated in the tank 33. When the supply unit 33f supplies molecular iodine (I₂), the first mixed liquid P1 contains molecular iodine (I₂). When the supply unit 33f supplies triiodide, the triiodide releases the triiodide ions (I₃⁻) into the first mixed liquid P1. Therefore, when the supply unit 33f supplies the triiodide, the first mixed liquid P1 contains the triiodide ions (I₃⁻). Therefore, the first mixed liquid P1 contains at least one of the molecular iodine (I₂) and the triiodide ions (I₃⁻). The tank 31 stores the first mixed liquid P1.

### Step S2a: Etching Step

The etching step is executed after the first preparation step. In the etching step, the first generation unit 24 sends the first mixed liquid P1 to the supply unit 15a. In the etching step, the supply unit 15a supplies the first mixed liquid P1 to the substrate W held by the substrate holding unit 13. The first layer G is exposed to the first mixed liquid P1. The first layer G is etched.

### 3-3. Effects of Third Embodiment

Also in the third embodiment, the same effects as those of the first and second embodiments are obtained.

The substrate processing method of the third embodiment includes the first preparation step. In the first preparation step, the first mixed liquid P1 is prepared. The first mixed liquid P1 is obtained by adding at least one of molecular iodine (I₂) and triiodide to the etching liquid. When the first mixed liquid P1 is prepared by adding the molecular iodine (I₂) to the etching liquid, the amount of the molecular iodine (I₂) in the first mixed liquid P1 is large. When the first mixed liquid P1 is prepared by adding the triiodide to the etching liquid, the amount of the triiodide ions (I₃⁻) in the first mixed liquid P1 is large. Therefore, at least one of the content of the molecular iodine (I₂) in the first mixed liquid P1 and the content of the triiodide ions (I₃⁻) in the first mixed liquid P1 is high.

The substrate processing method of the third embodiment includes the etching step. In the etching step, the first mixed liquid P1 is supplied to the substrate W. The etching liquid etches the first layer G. At least one of the molecular iodine (I₂) and the triiodide ions (I₃⁻) assists the etching of the first layer G. As described above, the first mixed liquid P1 abundantly contains at least one of the molecular iodine (I₂) and the triiodide ions (I₃⁻). Therefore, even when the first layer G is small, the first layer G is appropriately etched in the etching step.

As described above, according to the substrate processing method of the third embodiment, the first layer G can be appropriately etched even when the first layer G is small.

Triiodide includes, for example, at least one of nitrogen triiodide, phosphorus triiodide, and ammonium triiodide. Nitrogen triiodide readily releases the triiodide ions (I₃⁻). Therefore, when the triiodide includes nitrogen triiodide, it is easy to prepare the first mixed liquid P1 rich in triiodide ions (I₃⁻). Similarly, phosphorus triiodide readily releases the triiodide ions (I₃⁻). Therefore, when the triiodide includes phosphorus triiodide, it is easy to prepare the first mixed liquid P1 rich in triiodide ions (I₃⁻). Ammonium triiodide readily releases the triiodide ions (I₃⁻). Therefore, when the triiodide includes ammonium triiodide, it is easy to prepare the first mixed liquid P1 rich in triiodide ions (I₃⁻).

The substrate processing apparatus 1 of the third embodiment includes the first generation unit 24. The first generation unit 24 generates the first mixed liquid P1. The first mixed liquid P1 is obtained by adding at least one of molecular iodine (I₂) and triiodide to the etching liquid. When the first mixed liquid P1 is generated by adding the molecular iodine (I₂) to the etching liquid, the amount of the molecular iodine (I₂) in the first mixed liquid P1 is large. When the first mixed liquid P1 is generated by adding the triiodide to the etching liquid, the amount of the triiodide ions (I₃⁻) in the first mixed liquid P1 is large. Therefore, at least one of the content of the molecular iodine (I₂) in the first mixed liquid P1 and the content of the triiodide ions (I₃⁻) in the first mixed liquid P1 is high.

The supply unit 15a supplies the first mixed liquid P1 to the substrate W. The etching liquid etches the first layer G. At least one of the molecular iodine (I₂) and the triiodide ions (I₃⁻) assists the etching of the first layer G. As described above, the first mixed liquid P1 abundantly contains at least one of the molecular iodine (I₂) and the triiodide ions (I₃⁻). Therefore, even when the first layer G is small, the first layer P is appropriately etched.

As described above, according to the substrate processing apparatus 1 of the third embodiment, the first layer G can be appropriately etched even when the first layer G is small.

The first generation unit 24 includes the tank 33, the supply unit 33a, and the supply unit 33f. The supply unit 33a supplies the etching liquid R to the tank 33. The supply unit 33f supplies at least one of molecular iodine (I₂) and triiodide ions (I₃⁻) to the tank 33. Therefore, the first generation unit 24 suitably generates the first mixed liquid P1 in the tank 33.

The tank 33 stores the first mixed liquid P1. That is, the etching liquid and at least one of the molecular iodine (I₂) and the triiodide ions (I₃⁻) are stored in the same tank (that is, the tank 33). Therefore, the configuration of the first generation unit 24 is simple.

The first mixed liquid P1 of the third embodiment processes the substrate W. The substrate W includes the first layer G. The first layer G contains silicon oxide. The first mixed liquid P1 of the third embodiment contains an etching liquid. The etching liquid contains hydrogen fluoride. It is easy to etch silicon oxide with hydrogen fluoride. Therefore, the first mixed liquid P1 easily etches the first layer G.

The first mixed liquid P1 is obtained by adding at least one of molecular iodine (I₂) and triiodide to the etching liquid. When the first mixed liquid P1 is obtained by adding the molecular iodine (I₂) to the etching liquid, the amount of the molecular iodine (I₂) in the first mixed liquid P1 is large. When the first mixed liquid P1 is obtained by adding triiodide to the etching liquid, the amount of the triiodide ions (I₃⁻) in the first mixed liquid P1 is large. Therefore, at least one of the content of the molecular iodine (I₂) in the first mixed liquid P1 and the content of the triiodide ions (I₃⁻) in the first mixed liquid P1 is high. That is, the first mixed liquid P1 abundantly contains at least one of the molecular iodine (I₂) and the triiodide ions (I₃⁻). Here, at least one of the molecular iodine (I₂) and the triiodide ions (I₃⁻) assists etching of silicon oxide. Therefore, even when the first layer G is small, the first mixed liquid P1 appropriately etches the first layer G.

As described above, according to the first mixed liquid P1 of the third embodiment, the first layer G can be appropriately etched even when the first layer G is small.

### 4. Fourth Embodiment

A substrate processing apparatus 1 of a fourth embodiment will be described with reference to the drawings. Note that the same components as those of the first to third embodiments are denoted by the same reference numerals, and a detailed description thereof will be omitted.

In the fourth embodiment, the outline of the substrate processing apparatus 1, the structure of the substrate W, and the configuration of the processing unit 11 are substantially the same as those in the first embodiment. The substrate processing apparatus 1 of the fourth embodiment includes a supply source 23 and a second generation unit 25 instead of the first adjustment unit 21 of the first embodiment. The supply source 23 of the fourth embodiment is substantially the same as the supply source 23 of the second embodiment.

### 4-1. Configuration of Second Generation Unit 25

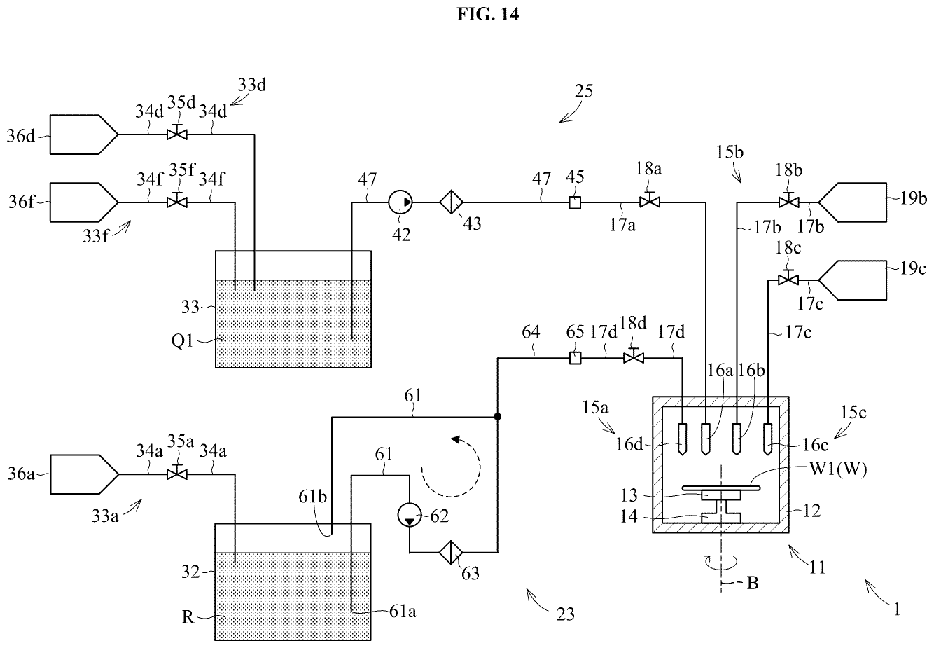

FIG. 14 is a diagram illustrating a configuration of the processing unit 11 and the second generation unit 25 of the fourth embodiment. The second generation unit 25 generates a solution Q1. The solution Q1 is obtained by adding at least one of molecular iodine (I₂) and triiodide to a solvent. The second generation unit 25 sends the solution Q1 to the supply unit 15a. The supply source 23 sends an etching liquid R to the supply unit 15a. The supply unit 15a supplies the solution Q1 to the substrate W. The supply unit 15a supplies the etching liquid R to the substrate W.

The supply unit 15a of the fourth embodiment is an example of a second supply unit in the present invention. The solution Q1 of the fourth embodiment is an example of the first solution in the present invention.

Hereinafter, the solution Q1 is appropriately referred to as a “first solution Q1”.

A configuration of the second generation unit 25 will be exemplified.

The second generation unit 25 includes a tank 33, a supply unit 33d, and a supply unit 33f. The tank 33 stores the first solution Q1. The supply unit 33f supplies at least one of molecular iodine (I₂) and triiodide to the tank 33. Triiodide includes, for example, at least one of nitrogen triiodide, phosphorus triiodide, and ammonium triiodide. The supply unit 33d supplies the solvent to the tank 33. The solvent dissolves molecular iodine (I₂). The solvent dissolves triiodide. The solvent is, for example, deionized water (DIW).

The second generation unit 25 is connected to the supply unit 15a. The supply source 23 is connected to the supply unit 15a.

Here, the nozzle 16a is connected to the second generation unit 25. The nozzle 16a is not connected to the supply source 23. The nozzle 16a dispenses the first solution Q1. The nozzle 16a does not dispense the etching liquid R.

The supply unit 15a further includes a nozzle 16d. The nozzle 16d is installed inside the housing 12. The nozzle 16d is connected to the supply source 23. The nozzle 16d is not connected to the second generation unit 25. The nozzle 16d dispenses the etching liquid R. The nozzle 16d does not dispense the first solution Q1.

The supply unit 15a further includes a pipe 17d and a valve 18d. The pipe 17d is connected to the nozzle 16d. The valve 18d is provided on the pipe 17d. The valve 18d controls the dispensing of the etching liquid R by the nozzle 16d.

The supply source 23 includes a joint 65. The joint 65 joins the pipe 64 and the pipe 17d. Thus, the tank 32 is connected to the nozzle 16d via the pipes 17d and 64 and the circulation pipe 61.

When the valve 18a is closed, the second generation unit 25 does not send the first solution Q1 to the supply unit 15a. When the valve 18a is opened and the pump 42 is operated, the second generation unit 25 sends the first solution Q1 to the nozzle 16a.

When the valve 18d is closed, the supply source 23 does not send the etching liquid R to the supply unit 15a. When the valve 18d is opened and the pump 62 is operated, the supply source 23 sends the etching liquid R to the nozzle 16a.

Although not illustrated, the control unit 10 controls the valve 18d in addition to the valve 18a. The control unit 10 controls the supply source 23 and the second generation unit 25. The control unit 10 controls the supply units 33a, 33d, and 33f. The control unit 10 controls the valves 35a, 35d, and 35f. The control unit 10 controls the pumps 42 and 62.

### 4-2. Operation Example of Second Generation Unit 25, Supply Source 23, and Processing Unit 11

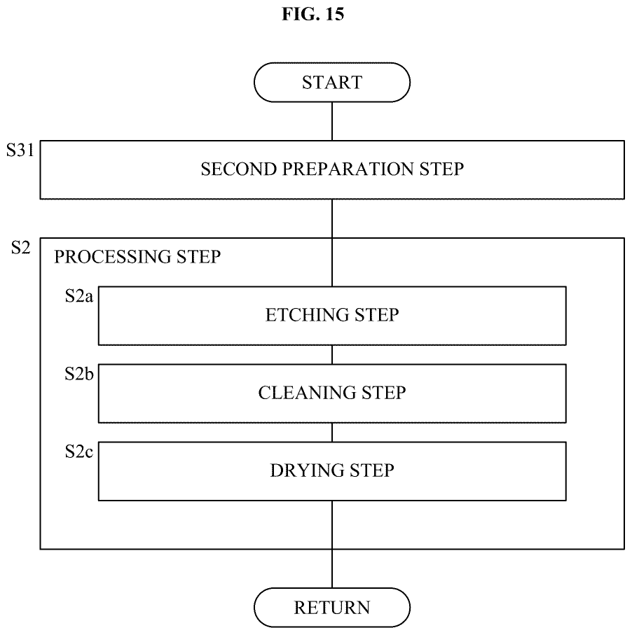

Refer to FIGS. 14 and 15. FIG. 14 is a flowchart illustrating a procedure of a substrate processing method of a fourth embodiment. The substrate processing method of the fourth embodiment includes a second preparation step instead of the first adjustment step of the first embodiment. In the fourth embodiment, a processing step is executed after the second preparation step. The operation of the processing step is substantially the same between the first embodiment and the fourth embodiment. The description of the washing step and the drying step in the processing step will be omitted.

### Step S31: Second Preparation Step

In the second preparation step, the second generation unit 25 prepares the first solution Q1. In the second preparation step, the second generation unit 25 adds at least one of molecular iodine (I₂) and triiodide to the solvent.

Specifically, the supply unit 33d supplies the solvent to the tank 33. The supply unit 33f supplies at least one of molecular iodine (I₂) and triiodide to the tank 33. As a result, the first solution Q1 is generated in the tank 33. The first solution Q1 contains at least one of molecular iodine (I₂) and triiodide ions (I₃⁻). The tank 31 stores the first solution Q1.

### Step S2a: Etching Step

The etching step is executed after the second preparation step. In the etching step, the second generation unit 25 sends the first solution Q1 to the supply unit 15a. In the etching step, the supply source 23 sends the etching liquid R to the supply unit 15a. In the etching step, the supply unit 15a supplies the first solution Q1 to the substrate W held by the substrate holding unit 13. In the etching step, the supply unit 15a supplies the etching liquid R to the substrate W held by the substrate holding unit 13. The supply unit 15a individually dispenses the first solution Q1 and the etching liquid R. Specifically, the nozzle 16a dispenses the first solution Q1 to the substrate W. The nozzle 16d dispenses the etching liquid R to the substrate W. The first solution Q1 and the etching liquid R are mixed on the substrate W.

The first layer G is exposed to the first solution Q1. The first layer G is exposed to the etching liquid R. The first layer G is etched.

### 4-3. Effects of Fourth Embodiment

Also in the fourth embodiment, the same effects as those of the first to third embodiments are obtained.

The substrate processing method of the fourth embodiment includes the second preparation step. In the second preparation step, the first solution Q1 is prepared. The first solution Q1 is obtained by adding at least one of molecular iodine (I₂) and triiodide to a solvent. When the first solution Q1 is prepared by adding the molecular iodine (I₂) to the solvent, the amount of the molecular iodine (I₂) in the first solution Q1 is large. When the first solution Q1 is prepared by adding the triiodide to the solvent, the amount of the triiodide ions (I₃⁻) in the first solution Q1 is large. Therefore, at least one of the content of the molecular iodine (I₂) in the first solution Q1 and the content of the triiodide ions (I₃⁻) in the first solution Q1 is high.

The substrate processing method of the fourth embodiment includes the etching step. In the etching step, the first solution Q1 is supplied to the substrate W. In the etching step, the etching liquid R is supplied to the substrate W. The etching liquid R etches the first layer G. At least one of the molecular iodine (I₂) and the triiodide ions (I₃⁻) assists the etching of the first layer G. As described above, the first solution Q1 abundantly contains at least one of the molecular iodine (I₂) and the triiodide ions (I₃⁻). Therefore, even when the first layer G is small, the first layer G is appropriately etched in the etching step.

As described above, according to the substrate processing method of the fourth embodiment, the first layer G can be appropriately etched even when the first layer G is small.

Triiodide includes, for example, at least one of nitrogen triiodide, phosphorus triiodide, and ammonium triiodide. Nitrogen triiodide readily releases the triiodide ions (I₃⁻). Therefore, when the triiodide includes nitrogen triiodide, it is easy to prepare the first solution Q1 rich in triiodide ions (I₃⁻). Similarly, phosphorus triiodide readily releases the triiodide ions (I₃⁻). Therefore, when the triiodide includes phosphorus triiodide, it is easy to prepare the first solution Q1 rich in triiodide ions (I₃⁻). Ammonium triiodide readily releases the triiodide ions (I₃⁻). Therefore, when the triiodide includes ammonium triiodide, it is easy to prepare the first solution Q1 rich in triiodide ions (I₃⁻).

The substrate processing apparatus 1 of the fourth embodiment includes the second generation unit 25. The second generation unit 25 generates the first solution Q1. The first solution Q1 is obtained by adding at least one of molecular iodine (I₂) and triiodide to a solvent. When the first solution Q1 is generated by adding the molecular iodine (I₂) to the solvent, the amount of the molecular iodine (I₂) in the first solution Q1 is large. When the first solution Q1 is generated by adding the triiodide to the solvent, the amount of the triiodide ions (I₃⁻) in the first solution Q1 is large. Therefore, at least one of the content of the molecular iodine (I₂) in the first solution Q1 and the content of the triiodide ions (I₃⁻) in the first solution Q1 is high.

The supply unit 15a supplies the first solution Q1 to the substrate W. The supply unit 15a supplies the etching liquid R to the substrate W. The etching liquid R etches the first layer G. At least one of the molecular iodine (I₂) and the triiodide ions (I₃⁻) assists the etching of the first layer G. As described above, the first solution Q1 abundantly contains at least one of the molecular iodine (I₂) and the triiodide ions (I₃⁻). Therefore, even when the first layer G is small, the first layer G is appropriately etched.

As described above, according to the substrate processing apparatus 1 of the fourth embodiment, the first layer G can be appropriately etched even when the first layer G is small.

The second generation unit 25 includes the tank 33 and the supply units 33d and 33f. The supply unit 33d supplies the solvent to the tank 33. The supply unit 33f supplies at least one of molecular iodine (I₂) and triiodide ions (I₃⁻) to the tank 33. Therefore, the second generation unit 25 suitably generates the first solution Q1 in the tank 33.

The tank 33 stores the first solution Q1. The tank 32 stores the etching liquid R. That is, the tank (that is, the tank 33) that stores the first solution Q1 is different from the tank (that is, the tank 32) that stores the etching liquid R. Therefore, the composition of the first solution Q1 in the tank 33 is not affected by the etching liquid R. Therefore, it is easy to manage the composition of the first solution Q1 in the tank 33. It is easy to manage the concentration of the first solution Q1. On the other hand, the composition of the etching liquid R in the tank 32 is not affected by the first solution Q1. Therefore, it is easy to manage the composition of the etching liquid R in the tank 32. It is easy to manage the concentration of the etching liquid R in the tank 32.

The present invention is not limited to the embodiments, and can be modified as follows.

(1) In the first adjustment step of the first embodiment, oxygen is added to the second mixed liquid P2. However, the present invention is not limited thereto. In the first adjustment step, at least one of oxygen and ozone may be added to the second mixed liquid P2. When ozone is added to the second mixed liquid P2, the iodide ions (I⁻) in the second mixed liquid P2 are oxidized. Therefore, at least one of the amount of the molecular iodine (I₂) in the second mixed liquid P2 and the amount of the triiodide ions (I₃⁻) in the second mixed liquid P2 increases.

The oxygen added to the second mixed liquid P2 in the first adjustment step preferably includes at least one of oxygen gas and high concentration oxygen water. By adding at least one of oxygen gas and high concentration oxygen water to the second mixed liquid P2, the iodide ions (I⁻) in the second mixed liquid P2 are easily oxidized. Therefore, it is easy to increase at least one of the amount of the molecular iodine (I₂) in the second mixed liquid P2 and the amount of the triiodide ions (I₃⁻) in the second mixed liquid P2 in the first adjustment step.

Here, the high concentration oxygen water is water containing oxygen at a concentration higher than usual. The amount of oxygen in high concentration oxygen water is greater than the amount of oxygen in water placed in normal air.

The ozone added to the second mixed liquid P2 in the first adjustment step preferably includes at least one of ozone gas and ozone water. By adding at least one of ozone gas and ozone water to the second mixed liquid P2, the iodide ions (I⁻) in the second mixed liquid P2 are easily oxidized. Therefore, it is easy to increase at least one of the amount of the molecular iodine (I₂) in the second mixed liquid P2 and the amount of the triiodide ions (I₃⁻) in the second mixed liquid P2 in the first adjustment step.

For example, in the first adjustment step of the first embodiment, the second mixed liquid P2 is exposed to air. However, the present invention is not limited thereto.

For example, in the first adjustment step, the second mixed liquid P2 may be exposed to an atmosphere of at least one of air, oxygen gas, and ozone gas. For example, in the first adjustment step, the second mixed liquid P2 may be exposed to an atmosphere of at least one of air, oxygen gas, and ozone gas for a predetermined time or more. Also in the first adjustment step of the present modification, at least one of oxygen and ozone is suitably added to the second mixed liquid P2.

For example, in the first adjustment step, at least one of air, oxygen gas, and ozone gas may be supplied above the second mixed liquid P2. For example, in the first adjustment step, at least one of air, oxygen gas, and ozone gas may be supplied to the upper portion of the tank 31. According to the first adjustment step of the present modification, an atmosphere of at least one of air, oxygen gas, and ozone gas is formed above the second mixed liquid P2.

For example, in the first adjustment step, at least one of air, oxygen gas, and ozone gas may be supplied into the second mixed liquid P2. For example, in the first adjustment step, at least one of air, oxygen gas, and ozone gas may be blown into the second mixed liquid P2. For example, in the first adjustment step, the second mixed liquid P2 may be bubbled by at least one of air, oxygen gas, and ozone gas. Also in the first adjustment step of the present modification, at least one of oxygen and ozone is suitably added to the second mixed liquid P2.

For example, in the first adjustment step, at least one of high concentration oxygen water and ozone water may be added to the second mixed liquid P2. For example, in the first adjustment step, at least one of high concentration oxygen water and ozone water may be supplied to the tank 31. Also in the first adjustment step of the present modification, at least one of oxygen and ozone is suitably added to the second mixed liquid P2.

(2) In the second adjustment step of the second embodiment, oxygen is added to the second solution Q2. However, the present invention is not limited thereto. In the second adjustment step, at least one of oxygen and ozone may be added to the second solution Q2. When ozone is added to the second solution Q2, the iodide ions (I⁻) in the second solution Q2 are oxidized. Therefore, at least one of the amount of the molecular iodine (I₂) in the second solution Q2 and the amount of the triiodide ions (I₃⁻) in the second solution Q2 increases.

The oxygen added to the second solution Q2 in the second adjustment step preferably includes at least one of oxygen gas and high concentration oxygen water. By adding at least one of oxygen gas and high concentration oxygen water to the second solution Q2, the iodide ions (I⁻) in the second solution Q2 are easily oxidized. Therefore, it is easy to increase at least one of the amount of the molecular iodine (I₂) in the second solution Q2 and the amount of the triiodide ions (I₃⁻) in the second solution Q2 in the second adjustment step.

The ozone added to the second solution Q2 in the second adjustment step preferably includes at least one of ozone gas and ozone water. By adding at least one of ozone gas and ozone water to the second solution Q2, the iodide ions (I⁻) in the second solution Q2 are easily oxidized. Therefore, it is easy to increase at least one of the amount of the molecular iodine (I₂) in the second solution Q2 and the amount of the triiodide ions (I₃⁻) in the second solution Q2 in the second adjustment step.

For example, in the second adjustment step of the second embodiment, oxygen is supplied into the second solution Q2. However, the present invention is not limited thereto.

For example, in the second adjustment step, the second solution Q2 may be exposed to an atmosphere of at least one of air, oxygen gas, and ozone gas. For example, in the second adjustment step, the second solution Q2 may be exposed to an atmosphere of at least one of air, oxygen gas, and ozone gas for a predetermined time or more. Also in the second adjustment step of the present modification, at least one of oxygen and ozone is suitably added to the second solution Q2.

For example, in the second adjustment step, at least one of air, oxygen gas, and ozone gas may be supplied above the second solution Q2. For example, in the second adjustment step, at least one of air, oxygen gas, and ozone gas may be supplied to the upper portion of the tank 31. According to the second adjustment step of the present modification, an atmosphere of at least one of air, oxygen gas, and ozone gas is formed above the second solution Q2.

For example, in the second adjustment step, at least one of air, oxygen gas, and ozone gas may be supplied into the second solution Q2. For example, in the second adjustment step, at least one of air, oxygen gas, and ozone gas may be blown into the second solution Q2. For example, in the second adjustment step, the second solution Q2 may be bubbled by at least one of air, oxygen gas, and ozone gas. Also in the second adjustment step of the present modification, at least one of oxygen and ozone is suitably added to the second solution Q2.

For example, in the second adjustment step, at least one of high concentration oxygen water and ozone water may be added to the second solution Q2. For example, in the second adjustment step, at least one of high concentration oxygen water and ozone water may be supplied to the tank 31. Also in the second adjustment step of the present modification, at least one of oxygen and ozone is suitably added to the second solution Q2.

(3) In the first preparation step of the third embodiment, at least one of oxygen and ozone may be further added to the first mixed liquid P1. According to the present modification, at least one of the content of the molecular iodine (I₂) in the first mixed liquid P1 and the content of the triiodide ions (I₃⁻) in the first mixed liquid P1 is still higher. At least one of the content of the molecular iodine (I₂) in the first mixed liquid P1 and the content of the triiodide ions (I₃⁻) in the first mixed liquid P1 is hardly reduced.

The oxygen added to the first mixed liquid P1 in the first preparation step preferably includes at least one of oxygen gas and high concentration oxygen water. By adding at least one of oxygen gas and high concentration oxygen water to the first mixed liquid P1, the iodide ions (I⁻) in the first mixed liquid P1 are easily oxidized. Therefore, it is easy to increase at least one of the amount of the molecular iodine (I₂) in the first mixed liquid P1 and the amount of the triiodide ions (I₃⁻) in the first mixed liquid P1.

The ozone added to the first mixed liquid P1 in the first preparation step preferably includes at least one of ozone gas and ozone water. By adding at least one of ozone gas and ozone water to the first mixed liquid P1, the iodide ions (I⁻) in the first mixed liquid P1 are easily oxidized. Therefore, it is easy to increase at least one of the amount of the molecular iodine (I₂) in the first mixed liquid P1 and the amount of the triiodide ions (I₃⁻) in the first mixed liquid P1.

For example, in the first preparation step, the first mixed liquid P1 may be exposed to an atmosphere of at least one of air, oxygen gas, and ozone gas. Also in the first preparation step of the present modification, at least one of oxygen and ozone is suitably added to the first mixed liquid P1.

For example, in the first preparation step, at least one of air, oxygen gas, and ozone gas may be supplied above the first mixed liquid P1. For example, in the first preparation step, at least one of air, oxygen gas, and ozone gas may be supplied to the upper portion of the tank 33. According to the first preparation step of the present modification, an atmosphere of at least one of air, oxygen gas, and ozone gas is formed above the first mixed liquid P1.

For example, in the first preparation step, at least one of air, oxygen gas, and ozone gas may be supplied into the first mixed liquid P1. For example, in the first preparation step, at least one of air, oxygen gas, and ozone gas may be blown into the first mixed liquid P1. For example, in the first preparation step, the first mixed liquid P1 may be bubbled by at least one of air, oxygen gas, and ozone gas. Also in the first preparation step of the present modification, at least one of oxygen and ozone is suitably added to the first mixed liquid P1.

For example, in the first preparation step, at least one of high concentration oxygen water and ozone water may be added to the first mixed liquid P1. For example, in the first preparation step, at least one of high concentration oxygen water and ozone water may be supplied to the tank 33. Also in the first preparation step of the present modification, at least one of oxygen and ozone is suitably added to the first mixed liquid P1.

(4) In the second preparation step of the fourth embodiment, at least one of oxygen and ozone may be further added to the first solution Q1. According to the present modification, at least one of the content of the molecular iodine (I₂) in the first solution Q1 and the content of the triiodide ions (I₃⁻) in the first solution Q1 is still higher. According to the present modification, at least one of the content of the molecular iodine (I₂) in the first solution Q1 and the content of the triiodide ions (I₃⁻) in the first solution Q1 is hardly reduced.

The oxygen added to the first solution Q1 in the second preparation step preferably includes at least one of oxygen gas and high concentration oxygen water. By adding at least one of oxygen gas and high concentration oxygen water to the first solution Q1, the iodide ions (I⁻) in the first solution Q1 are easily oxidized. Therefore, it is easy to increase at least one of the amount of the molecular iodine (I₂) in the first solution Q1 and the amount of the triiodide ions (I₃⁻) in the first solution Q1.

The ozone added to the first solution Q1 in the second preparation step preferably includes at least one of ozone gas and ozone water. By adding at least one of ozone gas and ozone water to the first solution Q1, the iodide ions (I⁻) in the first solution Q1 are easily oxidized. Therefore, it is easy to increase at least one of the amount of the molecular iodine (I₂) in the first solution Q1 and the amount of the triiodide ions (I₃⁻) in the first solution Q1.

For example, in the second preparation step, the first solution Q1 may be exposed to an atmosphere of at least one of air, oxygen gas, and ozone gas. Also in the second preparation step of the present modification, at least one of oxygen and ozone is suitably added to the first solution Q1.

For example, in the second preparation step, at least one of air, oxygen gas, and ozone gas may be supplied above the first solution Q1. For example, in the second preparation step, at least one of air, oxygen gas, and ozone gas may be supplied to the upper portion of the tank 33. According to the second preparation step of the present modification, an atmosphere of at least one of air, oxygen gas, and ozone gas is formed above the first solution Q1.

For example, in the second preparation step, at least one of air, oxygen gas, and ozone gas may be supplied into the first solution Q1. For example, in the second preparation step, at least one of air, oxygen gas, and ozone gas may be blown into the first solution Q1. For example, in the second preparation step, the first solution Q1 may be bubbled by at least one of air, oxygen gas, and ozone gas. Also in the second preparation step of the present modification, at least one of oxygen and ozone is suitably added to the first solution Q1.

For example, in the second preparation step, at least one of high concentration oxygen water and ozone water may be added to the first solution Q1. For example, in the second preparation step, at least one of high concentration oxygen water and ozone water may be supplied to the tank 33. Also in the second preparation step of the present modification, at least one of oxygen and ozone is suitably added to the first solution Q1.

(5) In the etching step of the second embodiment, the second solution Q2 and the etching liquid R are dispensed from the same nozzle (that is, the nozzle 16a). However, the present invention is not limited thereto. For example, the nozzle that dispenses the second solution Q2 may be different from the nozzle that dispenses the etching liquid R.

In the etching step of the fourth embodiment, the nozzle (that is, the nozzle 16a) that dispenses the first solution Q1 is different from the nozzle (that is, the nozzle 16d) that dispenses the etching liquid R. However, the present invention is not limited thereto. For example, the first solution Q1 and the etching liquid R may be dispensed from the same nozzle.

(6) The first generation unit 24 of the third embodiment does not have a configuration for circulating the first mixed liquid P1. However, the present invention is not limited thereto. For example, the first generation unit 24 may include the circulation pipe 41 of the first and second embodiments.

(7) The second generation unit 25 of the fourth embodiment does not have a configuration for circulating the first solution Q1. However, the present invention is not limited thereto. For example, the second generation unit 25 may include the circulation pipe 41 of the first and second embodiments.

(10) In the first to fourth embodiments, the first to fourth sensors 51 to 54 are exemplified. However, the present invention is not limited thereto. For example, the substrate processing apparatus 1 may include a sensor that detects the concentration of triiodide ions (I₃⁻) in at least one of the first mixed liquid P1, the second mixed liquid P2, the first solution Q1, and the second solution Q2. For example, the substrate processing apparatus 1 may include a sensor that detects the concentration of ozone in at least one of the first mixed liquid P1, the second mixed liquid P2, the first solution Q1, and the second solution Q2.

For example, in the first adjustment step of the first embodiment, at least one of a first detection result regarding the concentration of the molecular iodine (I₂) in the second mixed liquid P2, a second detection result regarding the concentration of the triiodide ions (I₃⁻) in the second mixed liquid P2, a third detection result regarding the concentration of oxygen in the second mixed liquid P2, and a fourth detection result regarding the concentration of ozone in the second mixed liquid P2 may be acquired. For example, the addition of at least one of oxygen and ozone to the second mixed liquid P2 may be stopped on the basis of at least one of the first detection result, the second detection result, the third detection result, and the fourth detection result. For example, the first adjustment step may be ended on the basis of at least one of the first detection result, the second detection result, the third detection result, and the fourth detection result. According to the present modification, the first adjustment step ends at an appropriate timing.

For example, in the second adjustment step of the second embodiment, at least one of a first detection result regarding the concentration of the molecular iodine (I₂) in the second solution Q2, a second detection result regarding the concentration of the triiodide ions (I₃⁻) in the second solution Q2, a third detection result regarding the concentration of oxygen in the second solution Q2, and a fourth detection result regarding the concentration of ozone in the second solution Q2 may be acquired. For example, the addition of at least one of oxygen and ozone to the second solution Q2 may be stopped on the basis of at least one of the first detection result, the second detection result, the third detection result, and the fourth detection result. For example, the second adjustment step may be ended on the basis of at least one of the first detection result, the second detection result, the third detection result, and the fourth detection result. According to the present modification, the second adjustment step ends at an appropriate timing.

For example, in the first preparation step of the third embodiment, at least one of a first detection result regarding the concentration of the molecular iodine (I₂) in the first mixed liquid P1 and a second detection result regarding the concentration of the triiodide ions (I₃⁻) in the first mixed liquid P1 may be acquired. For example, in the first preparation step of the third embodiment, at least one of the amount of the molecular iodine (I₂) added to the etching liquid and the amount of the triiodide added to the etching liquid may be adjusted on the basis of at least one of the first detection result and the second detection result.

For example, in the second preparation step of the fourth embodiment, at least one of a first detection result regarding the concentration of the molecular iodine (I₂) in the first solution Q1 and a second detection result regarding the concentration of the triiodide ions (I₃⁻) in the first solution Q1 may be acquired. For example, in the second preparation step of the fourth embodiment, at least one of the amount of the molecular iodine (I₂) added to the solvent and the amount of the triiodide added to the solvent may be adjusted on the basis of at least one of the first detection result and the second detection result.

For example, the substrate processing apparatus 1 may include a sensor that detects the amount of the second mixed liquid P2 in the tank 31. For example, the substrate processing apparatus 1 may include a sensor that detects the amount of the second solution Q2 in the tank 31. For example, the substrate processing apparatus 1 may include a sensor that detects the amount of the etching liquid R in the tank 32. For example, the substrate processing apparatus 1 may be provided with a sensor that detects the amount of the first mixed liquid P1 in the tank 33. For example, the substrate processing apparatus 1 may be provided with a sensor that detects the amount of the first solution Q1 in the tank 33.

For example, in the first adjustment step of the first embodiment, a detection result regarding the amount of the second mixed liquid P2 in the tank 31 may be acquired. For example, in the first adjustment step of the first embodiment, the second mixed liquid P2 may be generated in the tank 31 on the basis of the detection result regarding the amount of the second mixed liquid P2 in the tank 31. For example, in the first adjustment step of the first embodiment, the amount of the second mixed liquid P2 in the tank 31 may be adjusted on the basis of the detection result regarding the amount of the second mixed liquid P2 in the tank 31.

Similarly to the above-described modifications, the second to fourth embodiments may be modified.

(11) In the first to fourth embodiments, the first to fourth sensors 51 to 54 are provided on the circulation pipe 41. However, the present invention is not limited thereto. For example, at least one of the first to fourth sensors 51 to 54 may be provided on at least one of the tanks 31 to 33.

(12) In the first to fourth embodiments, the processing unit 11 is classified as a single wafer type. However, the present invention is not limited thereto. For example, the processing unit 11 in at least one of the first to fourth embodiments may be classified as a batch type. That is, the processing unit 11 may process a plurality of substrates W at a time. For example, the processing unit 11 classified as a batch type may execute the etching step in at least one of the first to fourth embodiments.

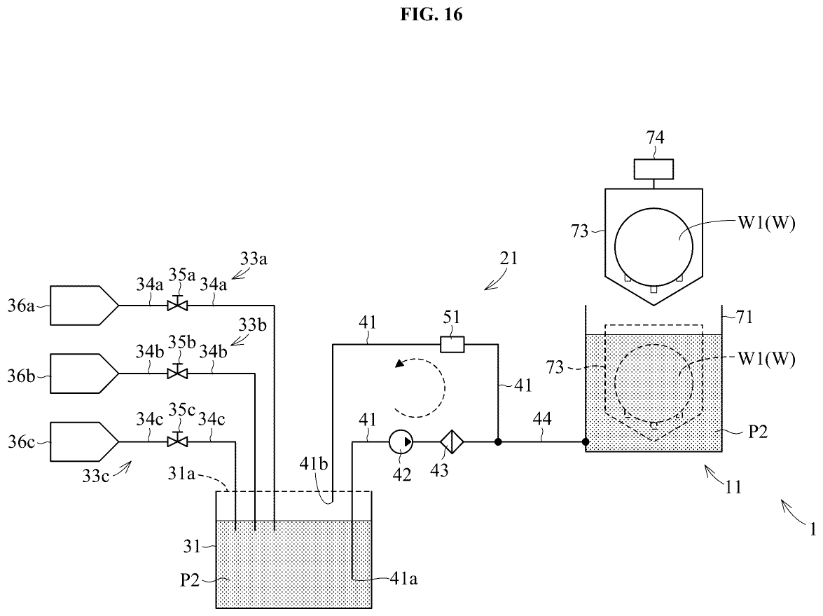

FIG. 16 is a diagram illustrating a configuration of a processing unit 11 and a first adjustment unit 21 of a modification. The modification illustrated in FIG. 16 corresponds to a combination of the first adjustment unit 21 and the processing unit 11 classified as a batch type. Note that the same components as those of the first embodiment are denoted by the same reference numerals, and a detailed description thereof will be omitted.

The processing unit 11 includes a tank 71. The tank 71 is connected to, for example, the first adjustment unit 21. After the first adjustment unit 21 adjusts the second mixed liquid P2, the first adjustment unit 21 sends the second mixed liquid P2 to the tank 71. The tank 71 stores the second mixed liquid P2 adjusted by the first adjustment unit 21.

The processing unit 11 includes a substrate holding unit 73. The substrate holding unit 73 simultaneously holds the plurality of substrates W. The substrate holding unit 73 holds each substrate W in a substantially vertical posture. When the substrate W is held by the substrate holding unit 73, the first surface W1 of each substrate W is substantially vertical.

The processing unit 11 includes an lift drive unit 74. The lift drive unit 74 is connected to the substrate holding unit 73. The lift drive unit 74 moves the substrate holding unit 73 in the vertical direction Z. The substrates W held by the substrate holding unit 73 move up and down integrally with the substrate holding unit 73.

The lift drive unit 74 moves the substrates W held by the substrate holding unit 73 to the upper position and the lower position. In FIG. 16, the substrates W and the substrate holding unit 73 when the substrates W are at the upper position are indicated by solid lines. In FIG. 16, the substrates W and the substrate holding unit 73 when the substrates W are at the lower position are indicated by broken lines. When the substrates W are located at the upper position, the substrates W are located above the second mixed liquid P2 in the tank 71. When the substrates W are at the lower position, the substrates W are immersed in the second mixed liquid P2 in the tank 71.

In the etching step, the tank 71 stores the second mixed liquid P2 adjusted by the first adjustment unit 21. In the etching step, the substrates W move from the upper position to the lower position. As a result, the second mixed liquid P2 in the tank 71 is supplied to the substrates W.

The tank 71 is an example of the first supply unit in the present invention.

In the modification illustrated in FIG. 16, the tank (that is, the tank 71) for supplying the second mixed liquid P2 to the substrates W is different from the tank (that is, the tank 31) for adjusting the second mixed liquid P2. However, the present invention is not limited thereto. For example, the tank for supplying the second mixed liquid P2 to the substrates W may be the same as the tank for adjusting the second mixed liquid P2. For example, the second mixed liquid P2 may be adjusted in the tank 71. Alternatively, the second mixed liquid P2 may be supplied to the substrates W in the tank 31. Specifically, the substrates W may be immersed in the second mixed liquid P2 in the tank 31.

(13) The embodiment and modified embodiments described in (1) to (12) above may be further varied as appropriate by replacing or combining their constructions with the constructions of the other modified embodiments.

### REFERENCE SIGNS LIST

1 substrate processing apparatus
10 control unit
11 processing unit
13 substrate holding unit
15a supply unit (first supply unit, second supply unit, third supply unit, fourth supply unit)
21 first adjustment unit
22 second adjustment unit
23 supply source
24 first generation unit
25 second generation unit
71 tank (first supply unit)
73 substrate holding unit
P1 mixed liquid (first mixed liquid, substrate processing liquid)
P2 mixed liquid (second mixed liquid)
Q1 solution (first solution)
Q2 solution (second solution)
R etching liquid
G first layer
Ga interlayer film
Gb blanket film
J, Ja, Jb second layer
K third layer
W substrate
W1 first surface
X front-rear direction
Y width direction
Z vertical direction

1. A substrate processing method for processing a substrate including a first layer, the method comprising:
a first preparation step of adding at least one of molecular iodine (I₂) and triiodide to an etching liquid to prepare a first mixed liquid; and
an etching step of supplying the first mixed liquid to the substrate to etch the first layer.

2. The substrate processing method according to claim 1, wherein
the first layer contains silicon oxide, and
the etching liquid contains hydrogen fluoride.

3. The substrate processing method according to claim 1, wherein
the substrate further includes:
a second layer having a composition different from a composition of the first layer; and
a third layer having a composition different from a composition of the first layer,
the first layer is disposed between the second layer and the third layer,
the second layer is in contact with the first layer,
the third layer is in contact with the first layer, and
in the etching step, the first layer is etched while suppressing etching of the second layer and the third layer.

4. The substrate processing method according to claim 3, wherein
the first layer contains silicon oxide,
the second layer contains at least one of single crystal silicon, polycrystalline silicon, amorphous silicon, and silicon nitride,
the third layer contains at least one of single crystal silicon, polycrystalline silicon, amorphous silicon, and silicon nitride, and
the etching liquid contains hydrogen fluoride.

5. (canceled)

6. (canceled)

7. (canceled)

8. (canceled)

9. A substrate processing method for processing a substrate including a first layer, the substrate processing method comprising:
a first adjustment step of adding at least one of oxygen and ozone to a second mixed liquid containing an etching liquid and iodide ions (I⁻); and
an etching step of supplying the second mixed liquid adjusted in the first adjustment step to the substrate to etch the first layer.

10. The substrate processing method according to claim 9, wherein
the first layer contains silicon oxide, and
the etching liquid contains hydrogen fluoride.

11. The substrate processing method according to claim 9, wherein
the substrate further includes:
a second layer having a composition different from a composition of the first layer; and
a third layer having a composition different from a composition of the first layer,
the first layer is disposed between the second layer and the third layer,
the second layer is in contact with the first layer,
the third layer is in contact with the first layer, and
in the etching step, the first layer is etched while suppressing etching of the second layer and the third layer.

12. The substrate processing method according to claim 11, wherein
the first layer contains silicon oxide,
the second layer contains at least one of single crystal silicon, polycrystalline silicon, amorphous silicon, and silicon nitride,
the third layer contains at least one of single crystal silicon, polycrystalline silicon, amorphous silicon, and silicon nitride, and
the etching liquid contains hydrogen fluoride.

13. (canceled)

14. (canceled)

15. (canceled)

16. (canceled)

17. A substrate processing apparatus that processes a substrate including a first layer, the substrate processing apparatus comprising:
a first generation unit that generates a first mixed liquid by adding at least one of molecular iodine (I₂) and triiodide to an etching liquid; and
a first supply unit that supplies the first mixed liquid to the substrate to etch the first layer.

18. (canceled)

19. (canceled)

20. (canceled)

21. A substrate processing liquid for processing a substrate including a first layer, wherein
the first layer contains silicon oxide,
the substrate processing liquid contains an etching liquid,
the etching liquid contains hydrogen fluoride, and
the substrate processing liquid is obtained by adding at least one of molecular iodine (I₂) and triiodide to the etching liquid.
